(19) United States
(12) Patent Application Publication
(10) Pub. No.: US 2009/0246712 A1
(43) Pub. Date: Oct. 1, 2009

(54) METHOD OF PRODUCING MULTILAYER OPTICAL RECORDING MEDIUM, STAMPER FOR PRODUCING MULTILAYER OPTICAL RECORDING MEDIUM, AND METHOD THEREFOR

(75) Inventor: Yukari Sumioka, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/160,204

(22) PCT Filed: Jan. 19, 2007
(86) PCT No.: PCT/JP2007/051207

§ 371 Date: Dec. 23, 2008

(30) Foreign Application Priority Data
Jan. 30, 2006 (JP) 2006-020895
Oct. 27, 2006 (JP) 2006-292528

(51) Int. Cl. G03F 7/20

(52) U.S. Cl. 430/321

(57) ABSTRACT

Provided is a stamper for producing a multilayer optical recording medium, which can be produced in simple steps and can be repeatedly used. Particularly, provided is a stamper for producing a multilayer optical recording medium, including: a translucent substrate; and a translucent inorganic resist layer in which a pit or a guide groove is formed on the substrate. Further, the stamper has an absorptivity of 10% or more with respect to exposure light which is used in patterning the inorganic resist layer, and has a transmittance of 19% or more with respect to an ultraviolet ray which is used when the stamper is used. Furthermore, the inorganic resist layer contains a tungsten oxide or a molybdenum oxide having a composition in which oxygen is lost from a stoichiometric composition.

### TECHNICAL FIELD

The present invention relates to a method of producing a multilayer optical recording medium, and particularly to a method of producing a multilayer optical recording medium, which includes forming a photoreactive curable resin to a substrate and stacking recording layers by spin coating or the like.

### BACKGROUND ART

As information recording/reproducing technology with a high recording density, an optical disk (optical recording medium) such as a DVD and a BD is attracting a great deal of attention. In recent years, in association with a movement toward digitalization of a moving image and a movement toward miniaturization of an apparatus, there is a demand for a higher recording density and a larger capacity.

In general, a recording density of an optical disk largely depends on a wavelength λ of a laser beam and a numerical aperture (NA) of an objective lens of a recording/reproducing optical system. In other words, a spatial frequency of recording pits capable of reproducing a signal is about 2 NA/λ. Accordingly, more studies have been conducted on the high recording density with employing a short wavelength technology or a high NA technology. For example, while a CD has a capacity of 650 MB when a wavelength of a laser beam for recording/reproduction is 780 nm and the NA of a lens is 0.45, a DVD-ROM has a capacity of 4.7 GB when a wavelength of a laser beam is 650 nm and the NA of a lens is 0.6. Further, a BD has a capacity of more than 23 GB when a wavelength of a laser beam is 405 nm and the NA of a lens is 0.85. Thus, a capacity of an optical disk has been increased.

On the other hand, more study has been conducted to realize a large capacity by stacking a plurality of recording layers. For example, a doubled recording capacity is realized in, for example, a DVD and a BD, by stacking two layers of recording layers. With regard to the BD, a four-layered medium is under development aiming at high integration to future generations.

The method of stacking a plurality of recording layers is proposed in Japanese Patent Application Laid-Open Nos. 2002-260307 and 2003-203402, Matsushita Technical Journal Vol. 50, No. 5, October 2004, p. 64-68, and the like.

Japanese Patent Application Laid-Open No. 2003-203402 and Matsushita Technical Journal Vol. 50, No. 5, October 2004, p. 64-68 propose a method of producing a multilayer optical recording medium, which includes forming pits or guide grooves in the surface of a substrate, forming a reflective layer and a recording layer thereon, forming a first information recording layer, and then repeating the following steps:

(1) forming an ultraviolet curable resin or a dry photopolymer on the first information recording layer,
(2) superimposing a resin stamper on the ultraviolet curable resin or the dry photopolymer, forming pits or guide grooves, and peeling a stamper, and
(3) forming a semitransparent film on the pits or the guide grooves.

However, in the above-mentioned proposal, there occurs an attenuation of the ultraviolet ray used for curing the ultraviolet curable resin or the dry photopolymer while using the semitransparent film, so that it is necessary to use a transparent stamper and conduct irradiation with the ultraviolet ray from a side of the stamper. For the transparent stamper, it is considered to use a stamper made of a resin, but it is difficult to reuse the stamper made of a resin in terms of productivity and quality thereof. Accordingly, the stamper is thrown away every formation of a layer, which leads to a problem in that costs thereof are increased.

Here, a conventional method of producing a multilayer optical recording medium is described below.

The conventional method of producing a multilayer optical recording medium will be described with reference to FIGS. 8A to 8P. In FIGS. 8A to 8P, there are provided four layers of information recording layers, that is, L0 layer to L3 layer. FIGS. 8A to 8P are vertical sections showing a half part of a rotationally-symmetrical disk having a center hole, and the center hole of each of the substrate and the stamper is omitted.

In FIG. 8A, a PC substrate 15 is a substrate made of a polycarbonate, which is obtained by injection molding using a stamper A 21 for injection molding, and information patterns 16 (pits or guide grooves) of an L0 layer are formed on the PC substrate 15. Typically, the PC substrate 15 has a thickness of 1.1 mm, a diameter of 120 mm, and a center hole diameter of 15 mm.

In FIG. 8B, on the information patterns 16 of the L0 layer, an L0 layer recording film 17 is formed. The L0 layer recording film 17 typically includes a reflective film which does not transmit light.

In FIG. 8C, an intermediate layer 3-forming 2p resin 18 for forming an intermediate layer 3 provided on the L0 layer between the L0 layer and the L1 layer is applied onto the L0 layer recording film 17. A thickness of the intermediate layer 3-forming 2p resin 18 is, for example, 10 μm. For simplification, the intermediate layer 3-forming 2p resin 18 is formed into a single layer, but a combination of a plurality of resins may be used therefor in order to satisfy a certain transfer property, releasability, and thickness accuracy.

In FIG. 8D, on the intermediate layer 3-forming 2p resin 18, a transparent stamper A 19-1 made of a resin in which information patterns of the L1 layer have been formed in advance is aligned using a center hole (not shown) to be superimposed thereon. After that, an ultraviolet ray from a UV light source 5 is irradiated thereon through the transparent stamper A 19-1 to cure the intermediate layer 3-forming 2p resin 18. The intermediate layer 3-forming 2p resin 18 may be superimposed on the L0 layer recording film 17 formed on the PC substrate 15 after being applied to the transparent stamper A 19-1.

In the FIG. 8E, after the intermediate layer 3-forming 2p resin 18 is cured, the transparent stamper A 19-1 is peeled and information patterns 13 (pits or guide grooves) of the L1 layer are formed on the PC substrate 15. The transparent stamper A 19-1 thus peeled deteriorates due to irradiation of the ultraviolet ray. As a result, the stamper cannot be reused as a stamper, and in addition, application thereof is limited even if the stamper is reused.

In FIG. 8F, on the information patterns 13 of the L1 layer, an L1 layer recording film 14 is formed. The L1 layer recording film 14 is formed of a semitransparent film.

In FIG. 8G, an intermediate layer 2-forming 2p resin 11 for forming an intermediate layer 2 provided on the L1 layer between the L1 layer and the L2 layer is applied onto the L1 layer recording film 14 in the same manner as described above. A thickness of the intermediate layer 2-forming 2p resin 11 is, for example, 15 μm.

In FIG. 8H, on the intermediate layer 2-forming 2p resin 11, a transparent stamper B 19-2 made of a resin in which information patterns of the L2 layer have been formed in advance is aligned using a center hole (not shown) to be superimposed thereon. After that, the ultraviolet ray from the UV light source 5 is irradiated thereon through the transparent stamper B 19-2 in the same manner as described above to cure the intermediate layer 2-forming 2p resin 11.

In FIG. 8I, after the intermediate layer 2-forming 2p resin 11 is cured, the transparent stamper B 19-2 is peeled and information patterns 9 (pits or guide grooves) of the L2 layer are formed on the PC substrate 15. In the same manner as described above, the transparent stamper B 19-2 thus peeled deteriorates due to irradiation of the ultraviolet ray, and cannot be reused as a stamper.

In FIG. 8J, on the information patterns 9 of the L2 layer, an L2 layer recording film 10 is formed. In the same manner as described above, the L2 layer recording film 10 is formed of a semitransparent film.

In FIG. 8K, an intermediate layer 1-forming 2p resin 7 for forming an intermediate layer 1 provided on the L2 layer between the L2 layer and the L3 layer is applied onto the L2 layer recording film 10 in the same manner as described above. A thickness of the intermediate layer 1-forming 2p resin 7 is, for example, 10 μm.

In FIG. 8L, on the intermediate layer 1-forming 2p resin 7, a transparent stamper C 19-3 made of a resin in which information patterns of the L3 layer have been formed in advance is aligned using a center hole (not shown) to be superimposed thereon. After that, in the same manner as described above, the ultraviolet ray from the UV light source 5 is irradiated thereon through the transparent stamper C 19-3 to cure the intermediate layer 1-forming 2p resin 7.

In FIG. 8M, after the intermediate layer 1-forming 2p resin 7 is cured, the transparent stamper C 19-3 is peeled and information patterns 4 (pits or guide grooves) of the L3 layer are formed on the PC substrate 15. In the same manner as described above, the transparent stamper C 19-3 thus peeled deteriorates due to irradiation of the ultraviolet ray, and cannot be reused as a stamper.

In FIG. 8N, on the information patterns 4 of the L3 layer, an L3 layer recording film 6 is formed. The L3 layer recording film 6 is formed of a semitransparent film as in the same manner as described above.

In FIG. 8O, onto the L3 layer recording film 6, a cover layer-forming 2p resin 2 for forming a cover layer is applied in the same manner as described above. A thickness of the cover layer-forming 2p resin 2 is, for example, 70 μm.

In FIG. 8P, the ultraviolet ray from the UV light source 5 is irradiated thereon to cure the cover layer-forming 2p resin 2. Instead of forming and curing the cover layer-forming 2p resin 2, a resin sheet having a thickness of 70 μm may be bonded.

Thus, in the conventional example, the transparent stampers A, B and C each made of a resin are used, but it is difficult to reuse the stampers in terms of productivity and quality thereof. For this reason, the stampers are thrown away after every formation of a layer, which leads to a problem in that costs thereof are increased. In particular, as the number of multilayers is increased, the problem of the increase in costs due to the disposal of the stamper made of a resin becomes more serious.

Japanese Patent Application Laid-Open No. H01-188332 proposes a method of forming patterns corresponding to information patterns in a glass material by etching, which is used as a transparent stamper. As shown in FIGS. 7A to 7E, onto a quartz glass substrate 71, a photoresist 72 is uniformly applied (FIG. 7A).

Next, on the photoresist 72, patterns corresponding to information patterns are recorded using a laser beam 73 (FIG. 7B), and then desired patterns are obtained by a developing treatment (FIG. 7C).

Then, dry etching is performed on the substrate in a CF₄ gas plasma 74, and the dry etching is stopped when each desired depth of etched portions is obtained (FIG. 7D). Further, the remaining photoresist 72 is subjected to ashing with oxygen (O₂) to be removed, thereby obtaining a stamper made of a glass (FIG. 7E).

The transparent stamper produced by the method disclosed by Japanese Patent Application Laid-Open No. H01-188332 can be repeatedly used, but it is necessary to manage a complicated process including the dry etching step and the ashing step. CF₄ gas or CHF₃ gas used for dry etching is known as greenhouse gas, and therefore it is desirable that those gases are not used therefor. Further, in the above-mentioned method, patterns are directly formed in the glass material, so that it is necessary to perform polishing when the glass material is reused.

### DISCLOSURE OF THE INVENTION

In order to solve the above-mentioned problems, there is provided a stamper for producing a multilayer optical recording medium, including:

a translucent substrate; and

a translucent inorganic resist layer in which pits or guide grooves are formed on the substrate.

There is provided a method of producing a stamper for producing a multilayer optical recording medium, including:

(a) a step of stacking a translucent inorganic resist layer on a translucent substrate; and

(b) a step of light-exposing and developing the inorganic resist layer to form pits or guide grooves.

Further, there is provided a method of producing a multilayer optical recording medium, including:

(a) a step of forming a recording layer on a support substrate;

(b) a step of forming an intermediate layer formed of a photoreactive curable resin onto the recording layer;

(c) a step of irradiating the intermediate layer with an ultraviolet ray through a stamper having pits or guide grooves formed on a translucent substrate by using an inorganic resist to transfer the pits or guide grooves onto the intermediate layer; and

(d) a step of stacking a recording layer on the intermediate layer.

Further, the stamper has an absorptivity of 10% or more with respect to exposure light which is used in patterning the inorganic resist layer, and has a transmittance of 19% or more with respect to an ultraviolet ray which is used when the stamper is used.

Further, the inorganic resist layer contains at least one of tungsten and molybdenum.

Further, the inorganic resist layer contains an oxide of tungsten or molybdenum, having a composition in which oxygen is lost from a stoichiometric composition.

The inorganic resist layer is formed of a resist of a negative type having a light-exposed part which is convex, or a positive type having a light-exposed part which is concave.

The substrate includes any one of glass, quartz, and transparent ceramic.

The optical recording medium according to the present invention includes an optical disk, an optical card, and an optical tape.

### BRIEF DESCRIPTION OF THE DRAWINGS

FIGS. 1A, 1B, 1C, 1D, 1E and 1F are schematic diagrams for explaining a method of producing an optical disk according to the present invention.

FIG. 2 is a sectional view of a double-layered optical recording medium.

FIGS. 3A, 3B, 3C, 3D, 3E, 3F, 3G, 3H and 3I are schematic diagrams for explaining a method of producing an optical disk according to Example 1 of the present invention.

FIGS. 4A, 4B, 4C, 4D, 4E, 4F and 4G are schematic diagrams for explaining a method of producing an optical disk according to Comparative Example 1 of the present invention.

FIGS. 5A, 5B, 5C, 5D, 5E, 5F, 5G, 5H, 5I, 5J, 5K, 5L, 5M, 5N, 5O, 5P, 5Q and 5R are schematic diagrams for explaining a method of producing an optical disk according to Example 2 of the present invention.

FIG. 6 is a sectional view of a four-layered optical recording medium.

FIGS. 7A, 7B, 7C, 7D and 7E are schematic diagrams for explaining a conventional method of producing a transparent stamper.

FIGS. 8A, 8B, 8C, 8D, 8E, 8F, 8G, 8H, 8I, 8J, 8K, 8L, 8M, 8N, 8O and 8P are sectional views for explaining steps in a conventional method of producing a four-layered recording medium.

FIGS. 9A, 9B, 9C, 9D, 9E, 9F and 9G are schematic diagrams for explaining a method of producing an optical disk according to Example 6 of the present invention.

FIGS. 10A, 10B, 10C, 10D, 10E, 10F and 10G are schematic diagrams for explaining a method of producing an optical disk according to Example 8 of the present invention.

FIGS. 11A, 11B, 11C, 11D, 11E, 11F and 11G are schematic diagrams for explaining a method of producing an optical disk according to Example 9 of the present invention.

### BEST MODE FOR CARRYING OUT THE INVENTION

An embodiment of the present invention will be described below.

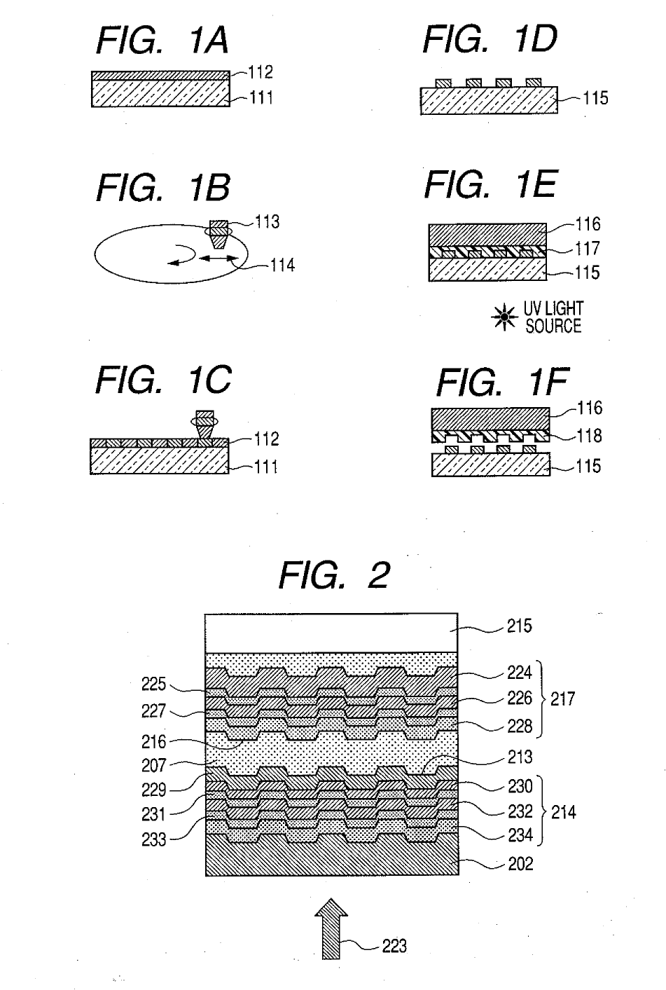

A concept of a method of producing an optical disk according to the present invention will be described with reference to FIGS. 1A to 1F. FIGS. 1A to 1F are schematic diagrams for explaining the method of producing an optical disk according to the present invention.

First, a stamper is described.

As shown in FIG. 1A, a resist 112 is formed on a transparent substrate 111. As the transparent substrate, a glass substrate, a quartz substrate, a transparent ceramic substrate, or the like may be used. The transparent substrate 111 preferably has a thickness for having an intensity and a transmittance sufficient for transferring information signal patterns. For example, the transparent substrate 111 preferably has a thickness of 0.5 mm to 20 mm, a diameter of 80 to 120 mm, and a center hole diameter of 10 to 15 mm. As a typical example, a description is made of a substrate having substantially the same diameter and center hole as those of a disk to be finally produced, for example, 120 mm and 15 mm, respectively.

As the resist, a tungsten oxide WO having a composition in which a slight amount of oxygen is lost from a stoichiometric composition, or WMoO obtained by adding molybdenum to WO may be used. A thickness of the resist 112 to be formed may be adjusted to obtain desired uneven pattern, and is preferably, for example, 20 nm to 1000 nm.

It is known that while an oxide of WO or WMoO has a considerably low absorption with respect to an ultraviolet ray in the stoichiometric composition, when a oxygen content is deviated from the stoichiometric composition only by a small amount, the absorption with respect to the ultraviolet ray becomes large. Thus, the resist in which the slight amount of oxygen is lost from the stoichiometric composition has a film whose state is changed by heat as a result of absorption of light for exposure. Further, in the resist, an etching rate with respect to an alkali solution is changed between a light-exposed part and a non-light-exposed part thereof, whereby the resist functions as a resist. In addition, the resist is formed of low molecules, so that a boundary between the light-exposed part and the non-light-exposed part appears clearly as compared with an organic resist formed of high molecules, thereby making it possible to obtain resist patterns with high accuracy.

Further, the resist has a high transmittance in a composition which has a small amount of oxygen deficiency and is approximate to the stoichiometric composition, and has a transmittance which becomes lower as the amount of oxygen deficiency becomes larger. In addition, in an ultraviolet range, as a wavelength of light becomes shorter, an absorptivity thereof becomes larger and the transmittance thereof becomes smaller. In other words, by adjusting the composition and the film thickness, it becomes possible to obtain a sufficient absorptivity with respect to the light for light exposure, and obtain a transmittance sufficient for curing with respect to the light for curing a photoreactive curable resin for forming an intermediate layer.

Here, by changing a film-forming condition, the WO functions as a negative type resist having a light-exposed part which becomes convex and also functions as a positive type resist having a light-exposed part which becomes concave. When the Mo is added to the WO little by little, sensitivity at the time of light exposure can be increased.

According to the present invention, the resist preferably has the absorptivity of 10% or more with respect to exposure light for light-exposing the resist. In addition, it is preferable to use a stamper which is obtained by forming uneven pattern corresponding to information patterns or guide grooves through development of the resist. Further, it is preferable that the stamper thus obtained has the transmittance of 15% or more at a wavelength having a transmittance which is highest in a wavelength bandwidth of an ultraviolet ray which is irradiated so as to cure the photoreactive curable resin. However, in view of a time for curing the photoreactive curable resin, the transmittance is preferably 19% or more at which effects can be obtained in several seconds.

FIG. 1B is a diagram of the transparent substrate 111 and the resist 112 obliquely viewed from above. Light 113 for light exposure is converged on the resist, and is moved toward a radius direction 114 of a glass substrate while the glass substrate is rotated, thereby performing pattern light exposure which has patterns corresponding to information patterns (pits or guide grooves) in a spiral manner from above the resist. At this time, as shown in FIG. 1C, a film state in a light-exposed region is changed. Further, as shown in FIG. 1D, development is performed under a condition in which a desired depth of each groove is obtained, to thereby obtain the information patterns (pits or guide grooves). The information patterns (pits or guide grooves) are formed in the resist (containing tungsten oxide) provided on the glass substrate, which is used as a transparent stamper 115.

The transparent stamper according to the present invention can be produced by simple procedures including film formation, light exposure, and development, without using an electrocasting apparatus, a back-surface polishing apparatus, an injection-molding machine, and an RIE apparatus which are conventionally necessary for producing a transparent stamper. Further, since the low-molecule resist is employed in the transparent stamper according to the present invention, it is possible to obtain information patterns with high accuracy.

Next, as shown in FIG. 1E, for example, a support substrate 116 onto which a photoreactive curable resin 117 for forming an intermediate layer is applied is superimposed on the transparent stamper 115. After that, the ultraviolet ray is irradiated thereon through the transparent stamper 115 to cure the photoreactive curable resin 117.

Next, as shown in FIG. 1F, the transparent stamper 115 is peeled from the support substrate 116, thereby forming information patterns 118 on the photoreactive curable resin 117.

The transparent stamper according to the present invention is made of an inorganic material, so that the transparent stamper does not deteriorate by irradiation with the ultraviolet ray, and can be repeatedly used.

Hereinafter, the method of producing an optical disk according to the present invention will be described in detail by referring to examples. However, the structure thereof is not limited thereto.

### Example 1

In this example, a description is made of a method of producing an optical disk having two information recording layers of an L0 layer and an L1 layer as one example. The L0 layer is formed using the transparent stamper according to the present invention. A description is made of a tungsten oxide WO, as an example, having a composition in which a slight amount of oxygen is lost from a stoichiometric composition as a resist. The tungsten oxide WO having the composition in which a slight amount of oxygen is lost from the stoichiometric composition used in Example 1 is a negative type resist having a film whose state is changed by being irradiated with light for light exposure, and having a light-exposed part which becomes convex through development using an alkali solution.

First, a description is made of a method of producing a transparent stamper for producing an optical disk according to Example 1.

The transparent stamper for producing an optical disk is produced by processes similar to those explained with reference to FIGS. 1A to 1F. As a transparent substrate, a quartz substrate having a thickness of 1 mm, an outer diameter of 120 mm, and an inner diameter of 15 mm was used. First, on the quartz substrate, a tungsten oxide WO having the composition in which a slight amount of oxygen is lost from a stoichiometric composition is formed. Sputtering was performed on a WOx target containing W in an atmosphere of Ar gas of 50 sccm and O₂ gas of 40 sccm, to thereby form the WO. The composition can be adjusted by changing a ratio of the Ar gas to the O₂ gas. A film thickness can be adjusted by a time for sputtering. In Example 1, a film thickness before light exposure is set to 100 nm, and a composition having an absorptivity of 10% with respect to light for light exposure having a wavelength of 351 nm was used.

Next, light exposure is performed. As explained with reference to FIG. 1B, the light for light exposure was converged on the resist, and was moved toward a radius direction of a quartz substrate while the quartz substrate was rotated, thereby performing pattern light exposure whose patterns correspond to information patterns 304 (pits or guide grooves) for forming an L0 layer from above the resist. In Example 1, a wavelength of the light for light exposure was 351 nm. As a condition for light-exposing a data recording area, a linear speed was set to 0.7 m/s, and power was set to 1.4 mW, and a track pitch TP was set to 320 nm.

Here, the film thickness of the resist at the time of light exposure, and the absorptivity with respect to the exposure light are not limited thereto. Also, the wavelength of the exposure light is not limited thereto. It is possible to select a combination of a condition (e.g., wavelength, linear speed, and power) under which the film state of the resist can be changed by light exposure, and a resist condition. The transmittance obtained after development is not limited, any transmittance may be adopted as long as the transmittance is sufficient to cure an intermediate layer-forming 2p resin as described later with the ultraviolet ray. The transmittance obtained after the development depends on the film thickness obtained after the development.

Next, the resist of the non-light-exposed part is removed using an alkali solution, and development is performed so that the depth of each groove of the data recording region becomes d=20 nm, to thereby produce a transparent stamper 300. In this case, each information track side thereof becomes convex with respect to the stamper substrate.

The transparent stamper 300 has a transmittance of 80% at the maximum with respect to light having a wavelength of 350 nm to 400 nm in a state after the development.

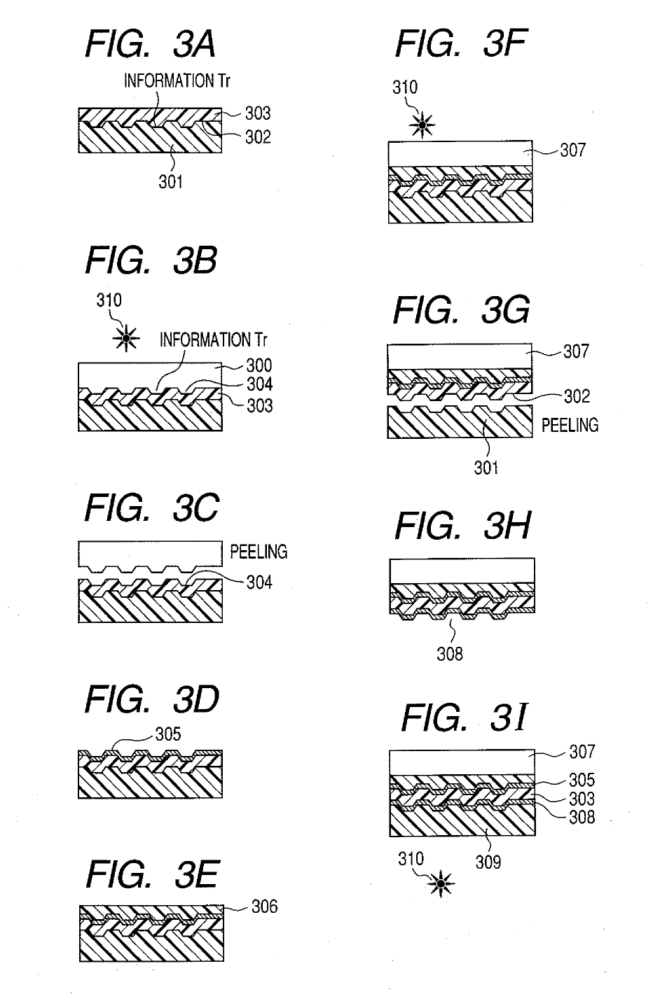

Next, a description is made of the method of producing an optical disk according to Example 1 with reference to FIGS. 3A to 3I. FIGS. 3A to 3I each show a sectional view of a half part of a rotationally-symmetrical disk having a center hole, and the center hole of each of the substrate and the stamper is omitted. All the steps are shown with an incident surface of a light beam for recording/reproduction facing downward.

As shown in FIG. 3A, information patterns 302 (pits or guide grooves) of the L1 layer are formed on a stamper A 301. It is not necessary that the stamper A 301 is transparent. The stamper A 301 is preferably made of, for example, nickel. The stamper A 301 preferably has a thickness of 0.2 to 2 mm, a diameter of 80 to 120 mm, and an inner diameter of 10 to 15 mm. Typically, the stamper A 301 has the thickness of 0.3 mm, and the diameter and the center hole diameter are substantially the same as those of a disk to be finally produced, for example, 120 mm and 15 mm, respectively. In this example, used was a nickel stamper having a thickness of 0.3 mm, an outer diameter of 120 mm, and an inner diameter of 15 mm, in which each information track (information Tr) became concave with respect to the stamper.

Onto the stamper A, an intermediate layer-forming 2p resin (photoreactive curable resin) 303 for forming an intermediate layer between the L0 layer and the L1 layer is applied. The intermediate layer-forming 2p resin 303 was dropped in an annular manner on an inner periphery side of the stamper A 301 having a center hole (not shown), and the stamper A 301 was rotated to shake off droplets, thereby obtaining a uniform thickness (first uniform thickness). As the intermediate layer-forming 2p resin 303, it is possible to appropriately select a resin from among resins which are curable by irradiation of an ultraviolet ray to be performed later. For example, an epoxy acrylate resin, a urethane acrylate resin, and a silicon acrylate resin are preferably used. A thickness of the intermediate layer-forming 2p resin 303 is, for example, 25 μm. For simplification, the intermediate layer-forming 2p resin 303 has a single layer, but a combination of a plurality of resins may be used therefor in order to satisfy a certain transfer property, releasability, and thickness accuracy.

As shown in FIG. 3B, the transparent stamper 300 is a transparent stamper containing the above-mentioned WO, and has information patterns 304 (pits or guide grooves) of the L0 layer formed therein. Each side of recording tracks (recording Tr) becomes a convex portion with respect to the stamper. The transparent stamper 300 was superimposed on the stamper A 301 onto which the intermediate layer-forming 2p resin 303 was applied, in a direction in which the information patterns 304 of the L0 layer were opposed to the information patterns 302 of the L1 layer. At this time, alignment thereof was performed using a center hole (not shown). After that, an ultraviolet ray (having a wavelength of 345 to 400 nm) from a UV light source 310 was irradiated thereon through the transparent stamper 300 to thereby cure the intermediate layer-forming 2p resin 303. In order to cure the intermediate layer-forming 2p resin 303, there was required a UV irradiation time of less than 2 seconds. In this case, the intermediate layer-forming 2p resin 303 may be superimposed on the stamper A after the resin is applied to the transparent stamper 300.

As shown in FIG. 3C, after the intermediate layer-forming 2p resin 303 is cured, the transparent stamper 300 is peeled, thereby forming the information patterns 304 of the L0 layer. The transparent stamper 300 thus peeled does not deteriorate even by being irradiated with the UV light beam and can be repeatedly used.

As shown in FIG. 3D, on the information patterns 304 of the L0 layer, an L0 layer recording film 305 was formed. The L0 layer recording film 305 typically includes a reflective layer which does not transmit light or a reflective layer. In this example, a dielectric film, an L0 recording film, a dielectric film, and an L0 reflective film were formed in the stated order by, for example, a sputtering method.

As shown in FIG. 3E, a bonding 2p resin 306 for bonding the L0 layer and the support substrate to each other is applied. The bonding 2p resin 306 was dropped in an annular manner on an inner periphery side of the stamper A 301 having a center hole (not shown), and the transparent stamper was rotated to shake off droplets, thereby obtaining a uniform thickness. The resin has a thickness of, for example, 10 to 20 μm, but may have any thickness as long as the thickness is uniform. It is not necessary to consider the transfer property of the bonding 2p resin 306, and it is sufficient to satisfy a certain adhesion and thickness accuracy. Accordingly, it is sufficient that the resin has a single layer structure.

As shown in FIG. 3F, a transparent support substrate 307 is superimposed on the stamper A 301. At this time, alignment thereof was performed using a center hole (not shown). After that, the ultraviolet ray from the UV light source 310 is irradiated thereon through the transparent support substrate 307 to thereby cure the bonding 2p resin 306.

As the transparent support substrate 307, a cycloolefin substrate, a polymethylmethacrylate (PMMA) substrate, a glass substrate, and the like are preferably used in addition to the polycarbonate (PC) substrate. The transparent support substrate 307 preferably has a thickness of 0.5 to 10 mm, a diameter of 80 to 120 mm, and a center hole diameter of 10 to 15 mm. Typically, the diameter and the center hole diameter thereof are substantially the same as those of a disk to be finally produced, and for example, 120 mm and 15 mm, respectively. In this example, used was a transparent PC support substrate having a thickness of 1.1 mm, a diameter of 120 mm, and a center hole diameter of 15 mm. In this case, with regard to the PC substrate, even when an optical characteristic such as a transmittance deteriorates due to the UV irradiation, a light beam for recording/reproduction does not pass through the transparent support substrate 307, so that there arises no problem.

As shown in FIG. 3G, after the transparent support substrate 307 is bonded, the stamper A is peeled, thereby forming the information patterns 302 of the L1 layer on the transparent support substrate 307.

As shown in FIG. 3H, on the information patterns 302 of the L1 layer, an L1 layer recording film 308 is formed. The L1 layer recording film 308 is formed of a semitransparent film. An L1 high refractive index film, an L1 reflective film, an L1 dielectric film, an L1 recording film, and a dielectric film were formed in the stated order by, for example, the sputtering method.

As shown in FIG. 3I, on the L1 layer recording film 308, a cover layer (resin protective layer) was formed. A cover layer-forming 2p resin 309 was dropped in an annular manner on an inner periphery side of the transparent support substrate 307 having a center hole (not shown), and the transparent support substrate 307 was rotated to shake off droplets, thereby obtaining a uniform thickness. As the cover layer-forming 2p resin 309, it is possible to appropriately select a resin from among resins which are curable by irradiation of an ultraviolet ray to be performed later. For example, an epoxy acrylate resin, a urethane acrylate resin, and a silicon acrylate resin are preferably used. A thickness of the cover layer-forming 2p resin 309 is preferably 40 to 100 μm, and is, for example, 75 μm. After that, the ultraviolet ray from the UV light source 310 is irradiated thereon to cure the cover layer-forming 2p resin 309, thereby completing the two-layered optical recording medium according to this example.

In this case, the structure of each of the recording films will be descried with reference to FIG. 2.

FIG. 2 is a sectional view of the completed two-layered optical recording medium according to Example 1. On a transparent support substrate 215, recording layers of an L0 layer 217 and an L1 layer 214 are disposed through an intermediate layer 207 from the transparent support substrate side, and a cover layer 202 covers the L1 layer 214. A light beam for recording/reproduction is made incident on the medium from a direction indicated by an arrow (incident direction of light beam for recording/reproduction) 223.

The recording films of L0 layer 217 and the L1 layer 214 will be described by illustrating a recordable film. Each of the recording films may be a recordable or rewritable film, or may be a combination thereof.

As shown in FIG. 3D, on information patterns 216 of the L0 layer, the L0 layer 217 is formed by the following procedures. First, on the information patterns 216 of the L0 layer which is formed on the intermediate layer 207, there are sequentially formed an L0 dielectric layer 228, an L0 intersurface layer 226 as needed, an L0 recording layer 226, an L0 intersurface layer 225 as needed, and an L0 reflective layer 224.

In other words, as the L0 layer 217 according to this example, layers are sequentially stacked from a layer of a side of the incident direction of the light beam for recording/reproduction, so that the dielectric layer, the recording layer, and the reflective layer are formed in the stated order.

As explained with reference to FIG. 3H, on the information patterns of the L1 layer, the L1 layer recording film is formed by the following procedures. First, on information patterns 213 of the L1 layer in which guide grooves or pits are formed, there are sequentially formed an L1 high refractive index layer 229 as needed, an L1 reflective layer 230, an L1 intersurface layer 231 as needed, an L1 recording layer 232, an L1 intersurface layer 233 as needed, and an L1 dielectric layer 234. In other words, on the information patterns, the reflective layer, the recording layer, and the dielectric layer are formed in the stated order.

In a general two-layered optical recording medium, layers are sequentially stacked from a layer of an opposite side of the incident direction of the light beam for recording/reproduction, so that the reflective layer, the recording layer, and the dielectric layer are formed in the stated order. For the reflective layer, a silver alloy or an aluminum alloy is mainly used, but a grain aggregate is formed in these materials at the time of film formation. For this reason, when the recording layer is formed after the reflective layer is formed, the recording layer has a shape reflecting the grain aggregate, and a groove shape which is preferable for the WO resist is buried, which leads to an increase in media noise and has an adverse effect on signals.

According to Example 1, the L0 layer has films sequentially stacked from a layer of a side of the incident direction of the light beam for recording/reproduction, so that the dielectric layer, the recording layer, and the reflective layer are formed in the stated order. In this case, the dielectric layer has an excellent surface property as compared with the reflective layer. As a result, according to this example, the surface property of the reflective layer is not adversely affected, and the characteristic of the groove shape which is preferable for the WO resist can be utilized.

The L0 layer according to Comparative Example 1 as described later is generally formed in the order of the reflective layer, the recording layer, and the dielectric layer. As compared with the L0 layer according to Comparative Example 1, a media noise generated in the L0 layer according to Example 1 was reduced by about 5 dB.

An evaluation of signal reproduction was performed with respect to the optical disk thus produced using an optical system having a laser wavelength of 405 nm and an objective lens with NA of 0.85, at a linear speed of 4.92 m/s, and using random data of (1-7) modulation having a capacity of 25 GB. When equalization was performed using a limit equalizer to measure a data-to-clock jitter, sufficient values of 5.0% in the L0 layer and 6.7% in the L1 layer were obtained.

According to the method of producing an optical disk of the present invention, the production steps are simple, and a transparent stamper which can be repeatedly utilized is used for other multilayer optical recording mediums, thereby making it possible to supply a multilayer optical disk at a low cost.

According to the method of producing an optical disk of this example, a transparent stamper of a negative type is used to stack layers from a side of the incident direction of the light beam for recording/reproduction, so that there is adopted a process of forming the reflective film after the recording film is formed. As a result, it is possible to obtain a preferable characteristic without being affected by a rough surface property of the reflective film.

### Comparative Example 1

In Comparative Example 1, a description is made of a method of producing an optical disk having two information recording layers, that is, an L0 layer and an L1 layer as a comparative example. For formation of the L1 layer, a transparent stamper made of a resin and formed by injection molding is used as a stamper for injection molding.

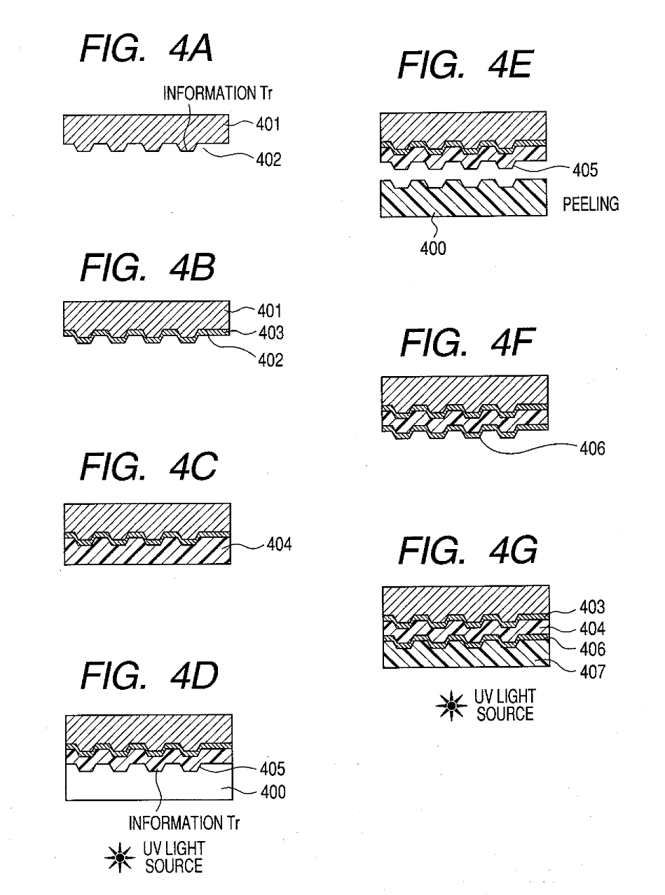

Next, with reference to FIGS. 4A to 4G, a description is made of the method of producing an optical disk according to Comparative Example 1. FIGS. 4A to 4G each show a sectional view of a half part of a rotationally-symmetrical disk having a center hole, and the center hole of each of the substrate and the stamper is omitted. All the steps are shown with an incident surface of a light beam for recording/reproduction facing downward.

First, as shown in FIG. 4A, by injection molding, a polycarbonate (PC) substrate 401 having a thickness of 1.1 mm, a diameter of 120 mm, and a center hole diameter of 15 mm, in which information patterns 402 (pits or guide grooves) of the L0 layer were formed, was formed. Each information track has a convex shape.

Next, as shown in FIG. 4B, on the information patterns 402 of the L0 layer, an L0 layer recording film 403 was formed. The L0 layer recording film 403 typically includes a reflective film which does not transmit light or a reflective film. In this example, an L0 reflective film, and a dielectric film, an L0 recording film, and a dielectric film were formed in the stated order by, for example, a sputtering method.

As shown in FIG. 4C, an intermediate layer forming-2p resin (photoreactive curable resin) 404 for forming an intermediate layer between the L0 layer and the L1 layer is applied thereto with a thickness of, for example, 25 μm, which is similar to that of Example 1.

As shown in FIG. 4D, a transparent stamper 400 is a transparent stamper made of a resin, and has information patterns 405 (pits or guide grooves) of the L1 layer formed therein. Each information track is concave with respect to the stamper. The polycarbonate (PC) substrate 401 into which the intermediate layer forming-2p resin 404 was applied was superimposed on the transparent stamper 400 in a direction in which the information patterns of the L0 layer were opposed to the information patterns of the L1 layer. At this time, alignment thereof was performed using a center hole (not shown). After that, the ultraviolet ray is irradiated thereon through the transparent stamper 400 to cure the intermediate layer forming-2p resin 404.

As shown in FIG. 4E, after the intermediate layer forming-2p resin 404 is cured, the transparent stamper 400 is peeled, thereby forming the information patterns 405 of the L1 layer. The transparent stamper 400 thus peeled deteriorates by being irradiated with the ultraviolet ray, and cannot be reused. In addition, even if the stamper is reused, the application of the stamper is limited.

As shown in FIG. 4F, on the information patterns 405 of the L1 layer, an L1 layer recording film 406 was formed. The L1 layer recording film 406 is formed of a semitransparent film. An L1 high refractive index film, an L1 reflective film, an L1 dielectric film, an L1 recording film, and a dielectric film were formed in the stated order by, for example, the sputtering method.

As shown in FIG. 4G, on the L1 layer recording film 406, a cover layer-forming 2p resin (resin protective layer) 407 was formed. In the same manner as in Example 1, the cover layer-forming 2p resin 407 was applied thereto with a thickness of, for example, 75 μm. After that, the ultraviolet ray from the UV light source is irradiated thereon to cure the cover layer-forming 2p resin 407, thereby completing the two-layered optical recording medium according to this example.

An evaluation of signal reproduction was performed with respect to the optical disk thus produced using an optical system having a laser wavelength of 405 nm and an objective lens with NA of 0.85, at a linear speed of 4.92 m/s, and using random data of (1-7) modulation having a capacity of 25 GB. When equalization was performed using a limit equalizer to measure a data-to-clock jitter, sufficient values of 6.0% in the L0 layer and 6.7% in the L1 layer were obtained.

In this comparative example, the transparent stamper 400 made of a resin was used only once to be thrown away. In addition, the media noise generated in the L0 layer was increased and the jitter value was made worse as compared with Example 1.

### Example 2

In this example, a description is made of a method of producing an optical disk having four information recording layers, that is, an L0 layer, an L1 layer, an L2 layer, and an L3 layer. All of the L0 layer, the L1 layer, the L2 layer, and the L3 layer are formed using a transparent stamper according to the present invention. As a resist for forming the transparent stamper, WO of a negative type resist which is similar to that of Example 1 is used.

First, by the steps similar to those of Example 1, an L0 layer-forming transparent stamper, an L1 layer-forming transparent stamper, an L2 layer-forming transparent stamper, and an L3 layer-forming transparent stamper were produced. In each of the stampers, light exposure patterns corresponding to information patterns (pits or guide grooves) for each of the L0 layer, the L1 layer, the L2 layer, and the L3 layer were formed. In this case, each information track side of each stamper was convex with respect to the stamper substrate.

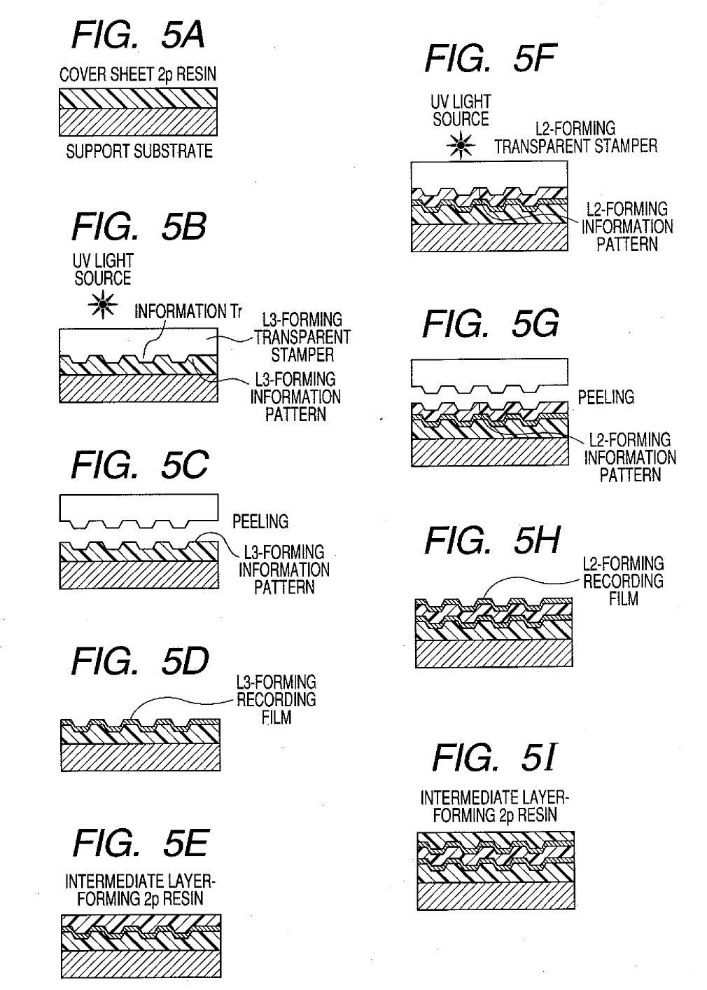

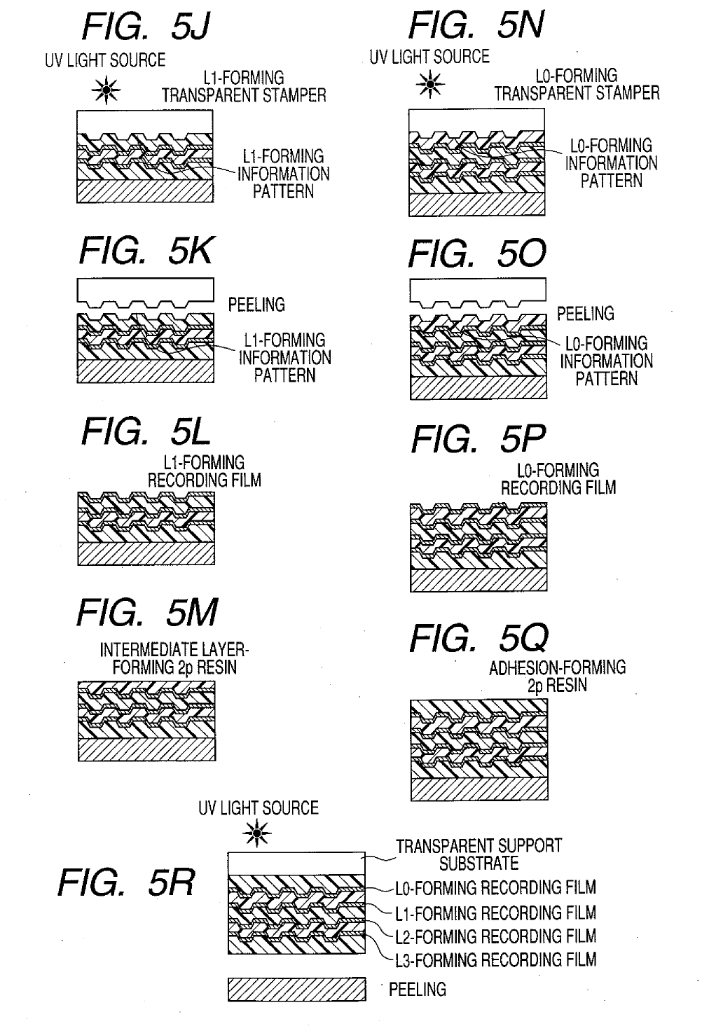

Next, with reference to FIGS. 5A to 5R, a description is made of the method of producing an optical disk according to Example 2. FIGS. 5A to 5R each show a sectional view of a half part of a rotationally-symmetrical disk having a center hole, and the center hole of each of the substrate and the stamper is omitted. All the steps are shown with an incident surface of a light beam for recording/reproduction facing downward. According to Example 2, the L3 layer, the L2 layer, the L1 layer, and the L0 layer were sequentially formed in the stated order from the L3 layer side.

As shown in FIG. 5A, onto a support substrate, a cover layer-forming 2p resin (photoreactive curable resin) for forming a cover layer (resin protective layer) was formed. Any support substrate may be used as long as the support substrate has a certain flatness (tilt characteristic and surface property) and intensity, and a resin substrate, a metal substrate, a glass substrate, or the like may be preferably used as the support substrate. It is not necessary that the support substrate is transparent, but the support substrate preferably has a thickness of 0.5 to 10 mm, a diameter of 80 to 150 mm, and an inner diameter of 10 to 15 mm. Typically, the diameter and the center hole diameter thereof are substantially the same as those of a disk to be finally produced, and for example, 120 mm and 15 mm, respectively. In this example, used was a glass substrate having a thickness of 1 mm, an outer diameter of 120 mm, and an inner diameter of 15 mm.

The cover layer-forming 2p resin was dropped in an annular manner on an inner periphery side of the glass substrate having a center hole (not shown), and the glass substrate was rotated to shake off droplets, thereby obtaining a uniform thickness. As the cover layer-forming 2p resin, similarly to that of Example 1, it is possible to appropriately select a resin from among resins which are curable by irradiation of an ultraviolet ray as performed later. A thickness of the cover layer-forming 2p resin is preferably 40 to 100 μm, and is, for example, 70 μm.

As shown in FIG. 5B, the L3-forming transparent stamper is a transparent stamper containing the above-mentioned WO, and has information patterns (pits or guide grooves) of the L3 layer formed therein. On the cover layer-forming 2p resin, the L3-forming transparent stamper was aligned using a center hole (not shown) to be superimposed thereon. After that, the ultraviolet ray was irradiated thereon through the L3-forming transparent stamper to cure the cover layer-forming 2p resin. The cover layer-forming 2p resin may be superimposed on the glass substrate after being applied to the L3-forming transparent stamper. For simplification, the cover layer-forming 2p resin has a single layer, but a combination of a plurality of resins may be used therefor in order to satisfy a certain transfer property, releasability, and thickness accuracy.

As shown in FIG. 5C, after the cover layer-forming 2p resin was cured, the L3-forming transparent stamper was peeled, thereby forming the information patterns (pits or guide grooves) of the L3 layer on the glass substrate. The L3-forming transparent stamper thus peeled does not deteriorate even by being irradiated with the UV light beam, and can be repeatedly used.

As shown in FIG. 5D, on the information patterns of the L3 layer, an L3 layer recording film was formed. The L3 layer recording film was formed of a semitransparent film.

As shown in FIG. 5E, onto the L3 layer recording film, an intermediate layer-forming 2p resin for forming an intermediate layer between the L3 layer and the L2 layer was applied. The intermediate layer-forming 2p resin was dropped on an inner periphery side of the glass substrate having a center hole (not shown) in an annular manner, and the glass substrate was rotated to shake off droplets, thereby obtaining a uniform thickness. As the intermediate layer-forming 2p resin, similarly to that of Example 1, it is possible to appropriately select a resin from among resins which are curable by irradiation of an ultraviolet ray to be performed later. A thickness of the intermediate layer-forming 2p resin is, for example, 10 μm.

As shown in FIG. 5F, the L2-forming transparent stamper is a transparent stamper containing the above-mentioned WO, and has information patterns (pits or guide grooves) of the L2 layer formed therein. The L2 -forming transparent stamper was aligned using a center hole (not shown) to be superimposed thereon. After that, the ultraviolet ray was irradiated thereon through the L2-forming transparent stamper to cure the cover layer-forming 2p resin. The intermediate layer-forming 2p resin may be superimposed on the glass substrate after being applied to the L2-forming transparent stamper. For simplification, the intermediate layer-forming 2p resin has a single layer, but a combination of a plurality of resins may be used therefor in order to satisfy a certain transfer property, releasability, and thickness accuracy.

As shown in FIG. 5G, after the intermediate layer-forming 2p resin was cured, the L2-forming transparent stamper was peeled, thereby forming information patterns (pits or guide grooves) of the L2 layer. The L2-forming transparent stamper thus peeled does not deteriorate even by being irradiated with the UV light beam, and can be repeatedly used.

As shown in FIG. 5H, on the information patterns of the L2 layer, an L2 layer recording film was formed. The L2 layer recording film was formed of a semitransparent film.

As shown in FIG. 5I, onto the L2 layer recording film, an intermediate layer-forming 2p resin for forming an intermediate layer between the L2 layer and the L1 layer was applied. The intermediate layer-forming 2p resin was dropped on an inner periphery side of the glass substrate having a center hole (not shown) in an annular manner, and the glass substrate was rotated to shake off droplets, thereby obtaining a uniform thickness. As the intermediate layer-forming 2p resin, similarly to that of Example 1, it is possible to appropriately select a resin from among resins which are curable by irradiation of an ultraviolet ray to be performed later. A thickness of the intermediate layer-forming 2p resin is, for example, 15 μm.

As shown in FIG. 5J, the L1-forming transparent stamper is a transparent stamper containing the above-mentioned WO, and has information patterns (pits or guide grooves) of the L1 layer formed therein. The L1-forming transparent stamper was aligned with the glass substrate using a center hole (not shown) to be superimposed thereon. After that, the ultraviolet ray was irradiated thereon through the L1-forming transparent stamper to cure the intermediate layer-forming 2p resin. The intermediate layer-forming 2p resin may be superimposed on the glass substrate after being applied to the L1-forming transparent stamper. For simplification, the intermediate layer-forming 2p resin has a single layer, but a combination of a plurality of resins may be used therefor in order to satisfy a certain transfer property, releasability, and thickness accuracy.

As shown in FIG. 5K, after the intermediate layer-forming 2p resin is cured, the L1-forming transparent stamper is peeled, thereby forming information patterns (pits or guide grooves) of the L1 layer. The L1-forming transparent stamper thus peeled does not deteriorate even by being irradiated with the UV light beam, and can be repeatedly used.

As shown in FIG. 5L, on the information patterns of the L1 layer, an L1 layer recording film was formed. The L1 layer recording film was formed of a semitransparent film.

As shown in FIG. 5M, onto the L1 layer recording film, an intermediate layer-forming 2p resin for forming an intermediate layer between the L1 layer and the L0 layer was applied. The intermediate layer-forming 2p resin was dropped on an inner periphery side of the glass substrate having a center hole (not shown) in an annular manner, and the glass substrate was rotated to shake off droplets, thereby obtaining a uniform thickness. As the intermediate layer-forming 2p resin, similarly to that of Example 1, it is possible to appropriately select a resin from among resins which are curable by irradiation of an ultraviolet ray to be performed later. A thickness of the intermediate layer-forming 2p resin is, for example, 10 μm.

As shown in FIG. 5N, an L0-forming transparent stamper is a transparent stamper containing the above-mentioned WO, and has information patterns (pits or guide grooves) of the L0 layer formed therein. The L0-forming transparent stamper was aligned with the glass substrate using a center hole (not shown) to be superimposed thereon. After that, the ultraviolet ray was irradiated thereon through the L0-forming transparent stamper to cure the intermediate layer-forming 2p resin. The intermediate layer-forming 2p resin may be superimposed on the glass substrate after being applied to the L0-forming transparent stamper. For simplification, the intermediate layer-forming 2p resin has a single layer, but a combination of a plurality of resins may be used therefor in order to satisfy a certain transfer property, releasability, and thickness accuracy.

As shown in FIG. 5O, after the intermediate layer-forming 2p resin was cured, the L0-forming transparent stamper was peeled, thereby forming information patterns (pits or guide grooves) of the L0 layer. The L0-forming transparent stamper thus peeled does not deteriorate even by being irradiated with the UV light beam, and can be repeatedly used.

As shown in FIG. 5P, on the information patterns of the L0 layer, an L0 layer recording film was formed. The L0 recording film typically includes a reflective layer which does not transmit light or a reflective layer.

As shown in FIG. 5Q, a bonding 2p resin for bonding the L0 layer and the support substrate was applied. The bonding 2p resin was dropped on an inner periphery side of the glass substrate having a center hole (not shown) in an annular manner, and the glass substrate was rotated to shake off droplets, thereby obtaining a uniform thickness. For the bonding 2p resin, similarly to that of Example 1, it is possible to appropriately select a resin from among resins which are curable by irradiation of an ultraviolet ray to be performed later. A thickness of the bonding 2p resin is, for example, 10 to 20 μm, but may have any thickness as long as the thickness is uniform. It is not necessary to consider the transfer property of the bonding 2p resin, and it is sufficient to satisfy a certain adhesion and thickness accuracy. Accordingly, it is sufficient that the bonding 2p resin has a single layer structure.

As shown in FIG. 5R, alignment of the transparent support substrate and the glass substrate was performed such that the transparent support substrate was superimposed on the glass substrate, using a center hole (not shown). After that, the ultraviolet ray was irradiated thereon through the transparent support substrate to cure the bonding 2p resin. For the transparent support substrate, a material similar to that of Example 1 is preferably used. As the transparent support substrate according to this example, preferably used was a transparent PC support substrate having a thickness of 1.1 mm, a diameter of 120 mm, and a center hole diameter of 15 mm. In this case, with regard to the PC substrate, even when an optical characteristic such as a transmittance deteriorates due to the UV irradiation, a light beam for recording/reproduction does not pass through the transparent support substrate, so there arises no problem.

As shown in FIG. 5R, after the bonding 2p resin was cured, the support substrate was peeled, thereby completing the four-layered optical disk according to Example 2.

Here, the structure of each of the recording films will be described.

As explained with reference to FIGS. 5D, 5H, 5L, and 5P, on the information patterns of each of the L3 layer to L0 layer, the L3 recording film to L0 layer recording film are respectively formed by the following procedure. First, on the information patterns of each of the L3 layer to L0 layer in which guide grooves or pits are formed, there are sequentially formed a dielectric layer, a surface layer as needed, a recording layer, a surface layer as needed, a reflective layer, and a high refractive index layer as needed. In other words, on the information patterns, the dielectric layer, the recording layer, and the reflective layer are formed in the stated order. In addition, as needed, a dielectric layer may be formed between the recording layer and the reflective layer.

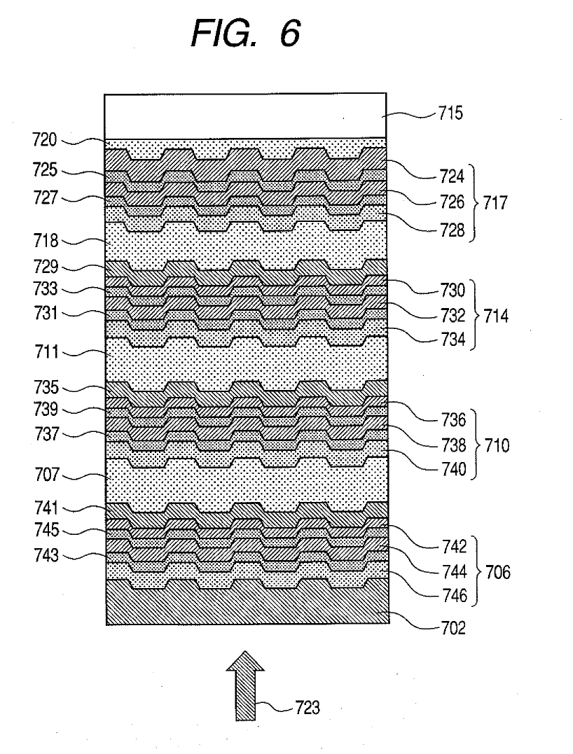

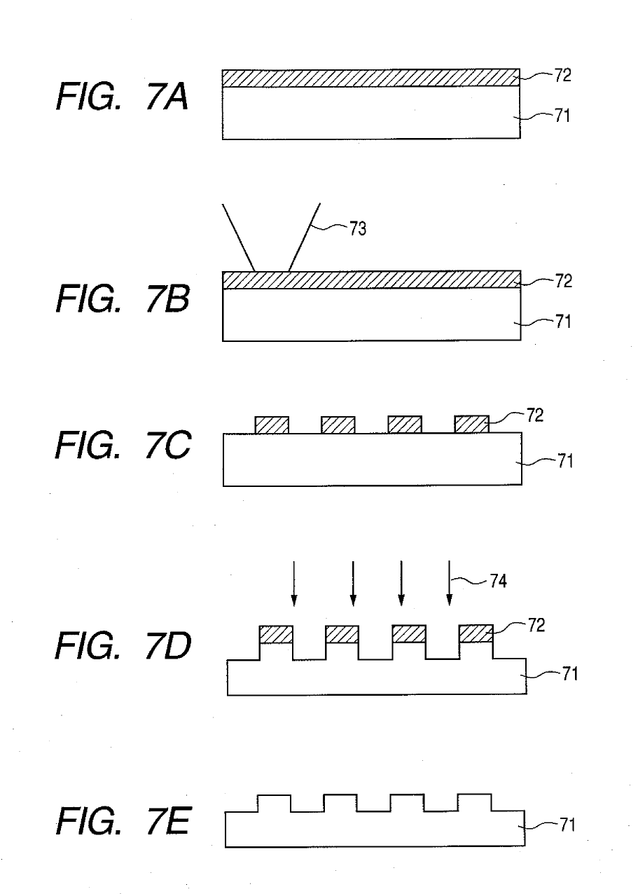

Next, with reference to FIG. 6, a description is made of the structure of each of the L0 layer recording film to L3 layer recording film. FIG. 6 is a sectional view of the completed four-layered optical recording medium according to this example. On a transparent support substrate 715, four recording layers, that is, an L0 layer 717, an L1 layer 714, an L2 layer 710, and an L3 layer 706 are disposed through an adhesive layer 720, and intermediate layers 718, 711, and 707, respectively, and a cover layer 702 covers the L3 layer. A light beam for recording/reproduction is made incident on the medium from a direction indicated by an arrow (of a light beam incident direction) 723.

The respective films 717, 714, 710, and 706 of L0 layer to L3 layer will be described by illustrating a recordable film. Each of the recording films may be a recordable or rewritable film, or may be a combination thereof.

As shown in FIG. 5D, on information patterns of the L3 layer, the L3 layer recording film is formed by the following procedure. First, on the information patterns of the L3 layer in which pits or guide grooves are formed therein, there are sequentially formed an L3 dielectric layer 746, an L3 surface layer 743 as needed, an L3 recording layer 744, an L3 surface layer 745 as needed, an L3 reflective layer 742, and an L3 high refractive index layer 741 as needed.

In other words, on the information patterns, the dielectric layer, the recording layer, and the reflective layer are formed in the stated order.

Similarly, as shown in FIG. 5H, on information patterns of the L2 layer, the L2 layer recording film 710 is formed by the following procedure. First, on the information patterns of the L2 layer in which guide grooves or pits are formed, there are sequentially formed an L2 dielectric layer 740, an L2 surface layer 737 as needed, an L2 recording layer 738, an L2 surface layer 739 as needed, an L2 reflective layer 736, and an L2 high refractive index layer 735 as needed. In other words, on the information patterns, the dielectric layer, the recording layer, and the reflective layer are formed in the stated order.

Similarly, as shown in FIG. 5L, on information patterns of the L1 layer, the L1 recording film 714 is formed by the following procedure. First, on the information patterns of the L1 layer in which guide grooves or pits are formed, there are sequentially formed an L1 dielectric layer 734, an L1 surface layer 731 as needed, an L1 recording layer 732, an L1 surface layer 733 as needed, an L1 reflective layer 730, and an L1 high refractive index layer 729 as needed. In other words, on the information patterns, the dielectric layer, the recording layer, and the reflective layer are formed in the stated order.

Similarly, as described with reference to FIG. 5P, on information patterns of the L0 layer, the L0 layer recording film 717 is formed by the following procedure. First, on the information patterns of the L0 layer in which guide grooves or pits are formed, there are sequentially formed an L0 dielectric layer 728, an L0 surface layer 727 as needed, an L0 recording layer 726, an L0 surface layer 725 as needed, and an L0 reflective layer 724. In other words, on the information patterns, the dielectric layer, the recording layer, and the reflective layer are formed in the stated order.

The conventional optical recording medium and the optical recording medium according to Comparative Example 2 to be described layer are formed in the order of the reflective layer, the recording layer, and the dielectric layer.

According to Example 2, all the layers are formed in the order of the dielectric layer, the recording layer, and the reflective layer. As a result, in all the layers, the surface property of the reflective layer is not adversely affected, and the characteristic of the groove shape which is preferable for the WO resist can be utilized, as described in Example 1.

As compared with the optical recording medium according to Comparative Example 2, a media noise generated in the L0 layer according to Example 2 was reduced by about 2.5 dB.

An evaluation of signal reproduction was performed with respect to the optical disk thus produced using an optical system having a laser wavelength of 405 nm and an objective lens NA of 0.85, at a linear speed of 4.92 m/s, and using random data of (1-7) modulation having a capacity of 25 GB. When equalization was performed using a limit equalizer to measure a data-to-clock jitter, sufficient values of 5.5% in the L0 layer, 6.5% in the L1 layer, 6.7% in the L2 layer, and 6.0% in the L3 layer were obtained.

According to the method of producing an optical disk of the present invention, the production processes are simple, and a transparent stamper which can be repeatedly used is used, thereby making it possible to supply a multilayer optical disk at a low cost. According to the method of producing an optical disk of this example, the transparent stamper according to the present invention can be applied to all the layers, so an electrocasting apparatus or an injection-molding machine is not necessary any more. Thus, it becomes possible to supply the multilayer optical disk at a lower cost.

Further, according to the method of producing an optical disk of the present invention, a transparent stamper of a negative type is used to stack layers from a side of the incident direction of the light beam for recording/reproduction, so adopted is a process in which the reflective film is formed after the recording film is formed. As a result, it is possible to obtain a preferable characteristic without being affected by a rough surface property of the reflective film.

### Comparative Example 2

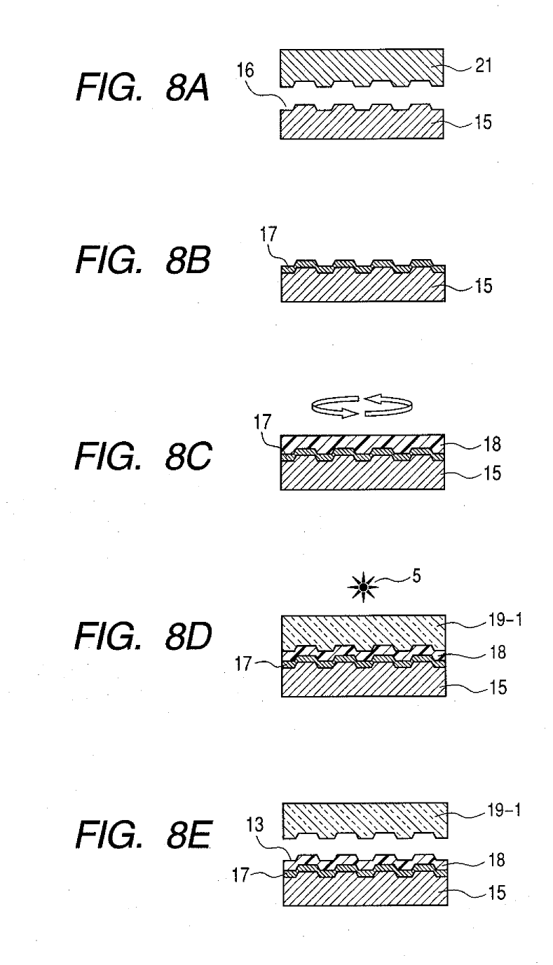

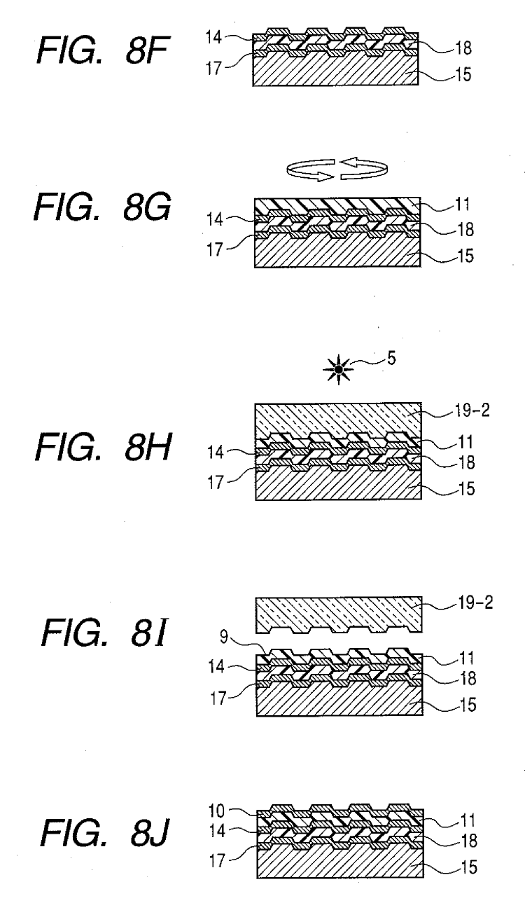

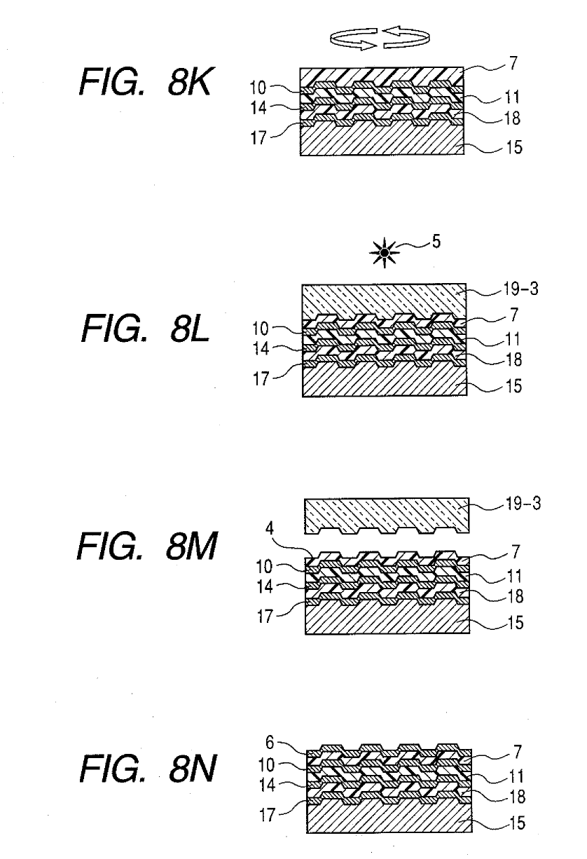

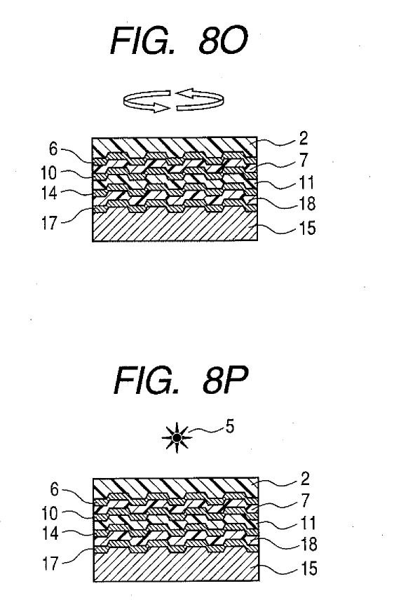

In Comparative Example 2, an optical disk having four information recording layers, that is, an L0 layer, an L1 layer, an L2 layer, and an L3 layer was produced by the method similar to that of the conventional example as shown in FIGS. 8A to 8P.

Here, the structure of each of the recording films is described.

As shown in FIG. 8B, on information patterns 16 of the L0 layer, an L0 layer recording film 17 was formed. The L0 layer recording film 17 typically includes a reflective film which does not transmit light or a reflective film.

In this example, an L0 reflective film, a dielectric film, an L0 recording film, and a dielectric film were formed in the stated order by, for example, the sputtering method.

As shown in FIG. 8F, on information patterns 13 of the L1 layer, an L1 layer recording film 14 was formed. The L1 layer recording film 14 is formed of a semitransparent film. An L1 high refractive index film, an L1 reflective film, an L1 dielectric film, an L1 recording film, and a dielectric film were formed in the stated order by, for example, the sputtering method.

As shown in FIG. 8J, on information patterns 9 of the L2 layer, an L2 layer recording film 10 was formed. The L2 layer recording film 10 is formed of a semitransparent film. An L2 high refractive index film, an L2 reflective film, an L2 dielectric film, an L2 recording film, and a dielectric film were formed in the stated order by, for example, the sputtering method.

As shown in FIG. 8N, on information patterns 5 of the L3 layer, an L3 layer recording film 6 was formed. The L3 layer recording film 6 is formed of a semitransparent film. An L3 high refractive index film, an L3 reflective film, an L3 dielectric film, an L3 recording film, and a dielectric film are formed in the stated order by, for example, the sputtering method.

According to Comparative Example 2, all the layers are formed in the order of the reflective layer, the recording layer, and the dielectric layer.

An evaluation of signal reproduction was performed with respect to the optical disk thus produced using an optical system having a laser wavelength of 405 nm and an objective lens NA of 0.85, at a linear speed of 4.92 m/s, and using random data of (1-7) modulation having a capacity of 25 GB. When equalization was performed using a limit equalizer to measure a data-to-clock jitter, sufficient values of 6.4% in the L0 layer, 7.1% in the L1 layer, 7.3% in the L2 layer, and 6.6% in the L3 layer were obtained.

In this comparative example, the transparent stampers A, B, and C each made of a resin were used only once to be thrown away, and each media noise generated in all the layers was increased and the jitter value was increased as compared with Example 2.

### Example 3

A stamper was produced by the method similar to that of Example 1 except that a composition of WO was changed in Example 3.

As a glass substrate, a quartz substrate having a thickness of 1 mm, an outer diameter of 120 mm, and an inner diameter of 15 mm was used. First, on the quartz substrate, a tungsten oxide WO having a composition in which a slight amount of oxygen was lost from the stoichiometric composition was formed. Sputtering was performed on a WOx target containing W in an atmosphere of Ar gas of 50 sccm and O₂ gas of 10 sccm, to thereby form the WO. As the composition, the ratio between the Ar gas and the O₂ gas was changed, thereby increasing an amount of oxygen deficiency as compared with Example 1. According to Example 3, used was a composition having a film thickness before exposure of 100 nm and an absorptivity of 70% with respect to the exposure light having a wavelength of 351 nm.

Next, the light for exposure was converged on the resist, and was moved toward a radius direction of the quartz substrate while the quartz substrate was rotated, thereby performing pattern exposure whose patterns correspond to information patterns (pits or guide grooves). According to Example 3, a wavelength of light for exposure was 351 nm. As a condition for exposing a data recording area, a linear speed was set to 2.0 m/s, and power was set to 2.0 mW, and a track pitch TP was set to 320 nm.

Next, the resist of the non-exposed part was removed using an alkali developer, and development was performed so that the depth of each groove of the data recording area be d=20 nm, to thereby produce a transparent stamper. Here, each information track side thereof is convex with respect to the stamper substrate.

The transparent stamper had a transmittance of 19% at the maximum with respect to light having a wavelength of 350 nm to 400 nm in a state after development.

Next, an optical disk was produced by the method similar to that of Example 1 except that a composition of WO was changed in Example 4. When the optical disk was evaluated in the same manner as in Example 1, the characteristic equivalent to that of Example 1 was obtained. The time necessary for UV irradiation to cure the intermediate layer-1 forming 2p resin was 5 seconds.

### Example 4

A stamper was produced by the method similar to that of Example 1 except that a composition of WO was changed in Example 4.

As a glass substrate, a quartz substrate having a thickness of 1 mm, an outer diameter of 120 mm, and an inner diameter of 15 mm was used. First, on the quartz substrate, a tungsten oxide WO having the composition in which a slight amount of oxygen was lost from the stoichiometric composition was formed. Sputtering was performed on a WOx target containing W in an atmosphere of Ar gas of 50 sccm and O₂ gas of 5 sccm, to thereby form the WO. As the composition, the ratio between the Ar gas and the O₂ gas was changed, thereby increasing an amount of oxygen deficiency as compared with Example 3. According to Example 4, used was a composition having the film thickness before exposure of 100 nm and the absorptivity of 75% with respect to the exposure light having a wavelength of 351 nm.

Next, the light for exposure was converged on the resist, and was moved toward a radius direction 114 of a glass substrate while the glass substrate was rotated, thereby performing pattern exposure whose patterns correspond to information patterns 304 (pits or guide grooves) of the L0 layer from above the resist. According to Example 4, a wavelength of light for exposure is 351 nm. As a condition for exposing a data recording area, a linear speed was set to 1.9 m/s, and power was set to 2.0 mW, and a track pitch TP was set to 320 nm.

Next, the resist of the exposed part was removed using an alkali solution, and development was performed so that the depth of each groove of the data recording area be d=20 nm, to thereby produce a transparent stamper. Here, each information track side thereof is a concave positive type with respect to the stamper substrate.

The transparent stamper had a transmittance of 15% at the maximum with respect to light having a wavelength of 350 nm to 400 nm in a state after development.

Next, when an optical disk was produced by the method of producing an optical disk similar to that of Example 1, it was required 60 seconds as the UV irradiation time to cure an intermediate layer 1-forming 2p resin 303.

### Comparative Example 3

A stamper was produced by the method similar to that of Example 1 except that a composition of WO was changed in Comparative Example 3.

As a glass substrate, a quartz substrate having a thickness of 1 mm, an outer diameter of 120 mm, and an inner diameter of 15 mm was used. First, on the quartz substrate, a tungsten oxide WO having the composition in which a slight amount of oxygen was lost from the stoichiometric composition was formed. Sputtering was performed on a WOx target containing W in an atmosphere of Ar gas of 50 sccm and O₂ gas of 50 sccm, to thereby form the WO. As the composition, the ratio between the Ar gas and the O₂ gas was changed, thereby increasing an amount of oxygen deficiency as compared with Example 1. According to Comparative Example 3, used was a composition having the film thickness before exposure of 100 nm and the absorptivity of 5% with respect to the exposure light having a wavelength of 351 nm.

Next, the light for exposure was converged on the resist, and exposure was performed while the quartz substrate was rotated. However, even when a high power was introduced thereto, the patterns could not be obtained.

### Example 5

In Example 5, a stamper was produced by the method similar to that of Example 3 except that a waveform of exposure light was changed to 405 nm.

As a glass substrate, a quartz substrate having a thickness of 1 mm, an outer diameter of 120 mm, and an inner diameter of 15 mm was used. First, on the quartz substrate, a tungsten oxide WO having the composition in which a slight amount of oxygen was lost from the stoichiometric composition was formed. Sputtering was performed on a WOx target containing W in an atmosphere of Ar gas of 50 sccm and O₂ gas of 10 sccm, to thereby form the WO. The film thickness before exposure was 100 nm, and the absorptivity was 30% with respect to the exposure light having a wavelength of 405 nm. In the vicinity of the ultraviolet range, as the wavelength of light becomes longer, the absorptivity becomes smaller.

Next, the light for exposure was converged on the resist, and was moved toward a radius direction of the quartz substrate while the quartz substrate was rotated, thereby performing pattern exposure whose patterns correspond to information patterns 304 (pits or guide grooves) of the L0 layer from above the resist. According to Example 5, a wavelength of light for exposure was 405 nm. As a condition for exposing a data recording area, a linear speed was set to 1.5 m/s, and power was set to 2.0 mW, and a track pitch TP was set to 320 nm.

Next, the resist of the non-exposed part was removed using an alkali developer, and development was performed so that the depth of each groove of the data recording area be d=20 nm, to thereby produce a transparent stamper. Here, each information track side thereof is convex with respect to the stamper substrate.

The transparent stamper had a transmittance of 19% at the maximum with respect to light having a wavelength of 350 nm to 400 nm in a state after development as in Example 3.

Next, an optical disk was produced by the method of producing an optical disk similar to that of Example 1. When the optical disk was evaluated in the same manner as in Example 1, the characteristic equivalent to that of Example 1 was obtained.

### Example 6

In Example 6, a stamper was produced using a W metal target.

As a glass substrate, a quartz substrate having a thickness of 1 mm, an outer diameter of 120 mm, and an inner diameter of 15 mm was used. First, on the quartz substrate, a tungsten oxide WO having the composition in which oxygen was lost from the stoichiometric composition was formed. Sputtering was performed on the W metal target in an atmosphere of Ar gas of 30 sccm and O₂ gas of 20 sccm, to thereby form the WO. The film thickness before exposure was 100 nm, and the absorptivity was 60% with respect to the exposure light having a wavelength of 351 nm.

Next, the light for exposure was converged on the resist, and was moved toward a radius direction of the quartz substrate while the quartz substrate was rotated, thereby performing pattern exposure whose patterns correspond to information patterns (pits or guide grooves) of the L1 layer from above the resist. In Example 6, as a condition for exposing a data recording area, a linear speed was set to 3.0 m/s, and power was set to 3.0 mW, and a track pitch TP was set to 320 nm. Here, the tungsten oxide WO having the composition in which oxygen is lost from the stoichiometric composition, which is used in Example 6, has a film whose state is changed by irradiation of light for exposure, and corresponds to a positive type resist in which the exposed part becomes concave by the development with the alkali solution.

Next, the resist of the exposed part is subjected to etching using the alkali developer, and development is performed so that the depth of each groove of the data recording area becomes d=20 nm, to thereby produce a transparent stamper 900. Each information track side thereof is concave with respect to the stamper.

The transparent stamper has a transmittance of 30% at the maximum with respect to the light having a wavelength of 350 nm to 400 nm in a state after the development.

Next, an optical disk was produced by the method which is similar to that of Comparative Example 1 except that the transparent stamper 900 according to the present invention was employed.

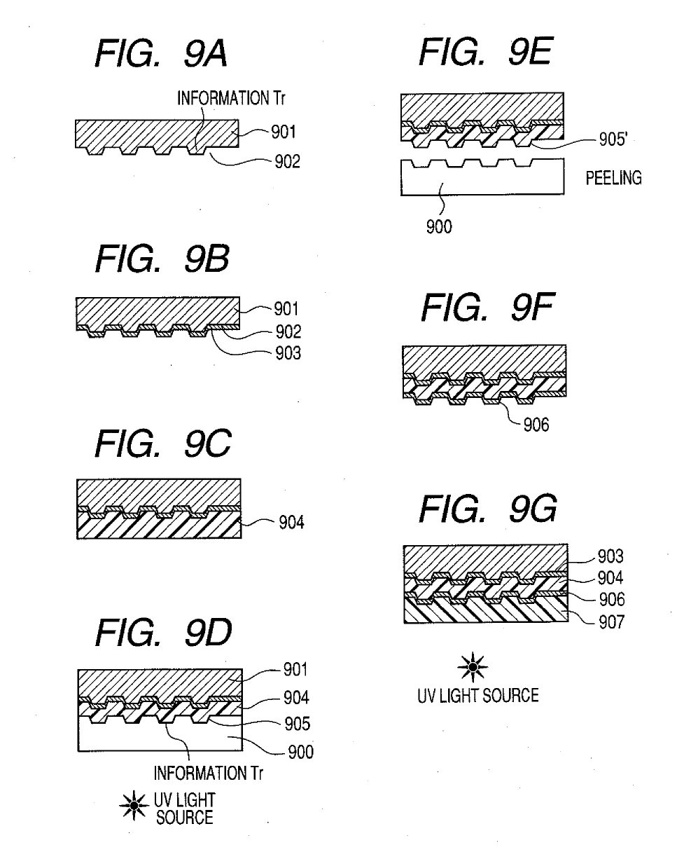

A description is made of the optical disk with reference to FIGS. 9A to 9G. FIGS. 9A to 9G each show a sectional view of a half part of disk having a center hole, and the center hole of each of the substrate and the stamper is omitted. All the processes are illustrated with an incident surface of a light beam for recording/reproduction facing downward.

First, as shown in FIG. 9A, by injection molding, a polycarbonate (PC) substrate 901 having a thickness of 1.1 mm, a diameter of 120 mm, and a center hole diameter of 15 mm, in which information patterns 902 (pits or guide grooves) of the L0 layer were formed, was formed. Each information track has a convex shape.

Next, as shown in FIG. 9B, on the information patterns 902 of the L0 layer, an L0 layer recording film 903 was formed. The L0 layer recording film 903 typically includes a reflective layer which does not transmit light or a reflective layer. According to this example, an L0 recording film, a dielectric film, an L0 recording film, and a dielectric film were formed in the stated order by, for example, a sputtering method.

As shown in FIG. 9C, an intermediate layer forming-2p resin (photoreactive curable resin) 904 for forming an intermediate layer between the L0 layer and the L1 layer is applied thereto with a thickness of, for example, 25 μm, which is similar to that of Example 1.

As shown in FIG. 9D, the transparent stamper 900 is a transparent stamper according to this example, and has information patterns 905 (pits or guide grooves) of the L1 layer formed therein. Each information track is concave with respect to the stamper. The polycarbonate (PC) substrate 901 applied with the intermediate layer forming-2p resin 904 was superimposed on the transparent stamper 900 in a direction in which the information patterns of the L0 layer were opposed to the information patterns of the L1 layer. At this time, alignment thereof was performed using a center hole (not shown). After that, the ultraviolet ray was irradiated thereon through the transparent stamper 900 to cure the intermediate layer forming-2p resin 904. In order to cure the intermediate layer-forming 2p resin 904, there was required UV irradiation time of less than 3 seconds.

As shown in FIG. 9E, after the intermediate layer forming-2p resin 904 is cured, the transparent stamper 900 is peeled, thereby forming the information patterns 905 of the L1 layer. The transparent stamper 900 thus peeled does not deteriorate even by being irradiated with the UV light beam, and can be repeatedly used.

As shown in FIG. 9F, on the information patterns 905 of the L1 layer, an L1 layer recording film 906 was formed. The L1 layer recording film 906 is formed of a semitransparent film. An L1 high refractive index film, an L1 reflective film, an L1 dielectric film, an L1 recording film, and a dielectric film were formed in the stated order by, for example, the sputtering method.

As shown in FIG. 9G, on the L1 layer recording film 906, a cover layer-forming 2p resin (resin protective layer) 907 was formed. In the same manner as in Example 1, the cover layer-forming 2p resin 907 was applied thereto with a thickness of, for example, 75 μm. After that, the ultraviolet ray from the UV light source was irradiated thereon to cure the cover layer-forming 2p resin 907, thereby completing the two-layered optical recording medium according to this example.

An evaluation of signal reproduction was performed with respect to the optical disk thus produced using an optical system having a laser wavelength of 405 nm and an objective lens NA of 0.85, at a linear speed of 4.92 m/s, and using random data of (1-7) modulation having a capacity of 25 GB. When equalization was performed using a limit equalizer to measure a data-to-clock jitter, values of 5.5% in the L0 layer and 6.7% in the L1 layer were obtained.

According to the method of producing an optical disk of the present invention, the production processes are simple, and a transparent stamper which can be repeatedly used is used, thereby making it possible to supply a multilayer optical disk at a low cost.

### Example 7

A transparent stamper was produced by the method similar to that of Example 6 except that a composition of WO was changed in Example 7.

As a glass substrate, a quartz substrate having a thickness of 1 mm, an outer diameter of 120 mm, and an inner diameter of 15 mm was used. First, on the quartz substrate, a tungsten oxide WO having the composition in which oxygen was lost from the stoichiometric composition was formed. Sputtering was performed on a W metal target in an atmosphere of Ar gas of 50 sccm and O₂ gas of 20 sccm, to thereby form the WO. In Example 7, used was a composition having the film thickness before exposure of 100 nm and the absorptivity of 70% with respect to the exposure light having a wavelength of 351 nm.

Next, the light for exposure was converged on the resist, and was moved toward a radius direction of the quartz substrate while the quartz substrate was rotated, thereby performing pattern exposure whose patterns correspond to information patterns (pits or guide grooves) of the L1 layer from above the resist. According to Example 7, as a condition for exposing a data recording area, a linear speed was set to 3.0 m/s, and power was set to 2.9 mW, and a track pitch TP was set to 320 nm.

Next, the resist of the non-exposed part was subjected to etching using an alkali developer, and development was performed so that the depth of each groove of the data recording area be d=20 nm, to thereby produce a transparent stamper. Here, each information track side thereof is concave with respect to the stamper substrate.

The transparent stamper had a transmittance of 19% at the maximum with respect to light having a wavelength of 350 nm to 400 nm in a state after development.

Next, an optical disk was produced by the method of producing an optical disk similar to that of Example 6. When the optical disk was evaluated in the same manner as in Example 6, the characteristic equivalent to that of Example 6 was obtained. The time necessary for UV irradiation was 5 seconds.

### Example 8

A transparent stamper was produced by the method similar to that of Example 6 except that a composition of WO was changed in Example 8.

As a glass substrate, a quartz substrate having a thickness of 1 mm, an outer diameter of 120 mm, and an inner diameter of 15 mm was used. First, on the quartz substrate, a tungsten oxide WO having the composition in which oxygen was lost from the stoichiometric composition was formed. Sputtering was performed on a WOx target containing W in an atmosphere of Ar gas of 15 sccm and O₂ gas of 16 sccm, to thereby form the WO. According to Example 8, used was a composition having the film thickness before exposure of 100 nm and the absorptivity of 50% with respect to the exposure light having a wavelength of 351 nm.

Next, the light for exposure was converged on the resist, and was moved toward a radius direction of the quartz substrate while the glass substrate was rotated, thereby performing pattern exposure whose patterns correspond to information patterns (pits or guide grooves) of the L1 layer from above the resist. According to Example 8, as a condition for exposing a data recording area, a linear speed was set to 1.0 m/s, and power was set to 2.5 mW, and a track pitch TP was set to 320 nm. Here, the tungsten oxide WO having the composition in which oxygen is lost from the stoichiometric composition, which is used in Example 8, has a film whose state is changed by irradiation of light for exposure, and corresponds to a negative type resist in which the exposed part becomes convex by the development with the alkali developer.

Next, the resist of the non-exposed part was subjected to etching using the alkali developer, and development was performed so that the depth of each groove of the data recording area be d=20 nm, to thereby produce a transparent stamper 1000. Here, each information track side thereof is a convex with respect to the stamper.

The transparent stamper had a transmittance of 40% at the maximum with respect to light having a wavelength of 350 nm to 400 nm in a state after development.

Next, in Example 8, an optical disk was produced by the method similar to that of Example 6 except that the transparent stamper 1000 according to the present invention and the L0 layer-forming substrate with information tracks each having a concave shape were used, and an organic recording material was used.

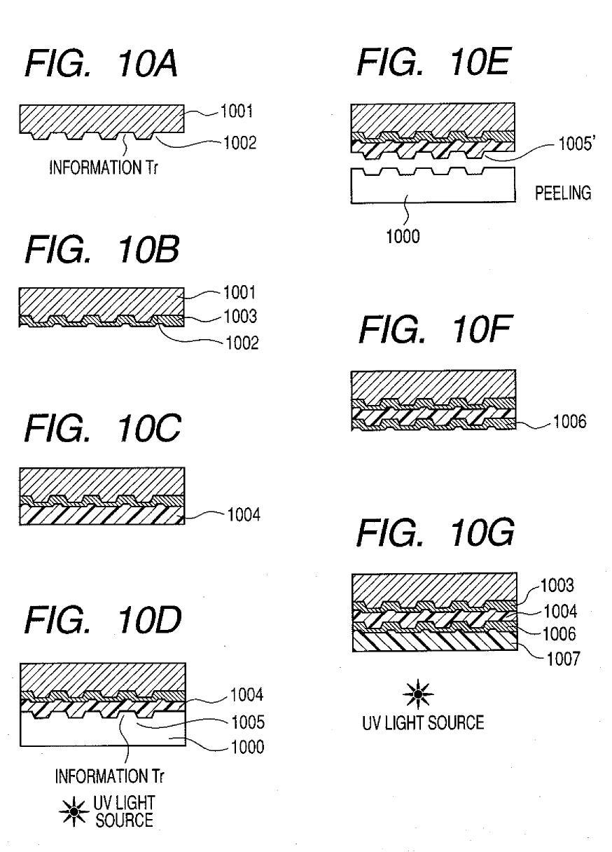

A description is made of the optical disk with reference to FIGS. 10A to 10G. FIGS. 10A to 10G each show a sectional view of a half part of a disk having a center hole, and the center hole of each of the substrate and the stamper is omitted. All the processes are illustrated with an incident surface of a light beam for recording/reproduction facing downward.

First, as shown in FIG. 10A, by injection molding, a polycarbonate (PC) substrate 1001 having a thickness of 1.1 mm, a diameter of 120 mm, and a center hole diameter of 15 mm, in which information patterns 1002 (pits or guide grooves) of the L0 layer were formed, was formed. Each information track has a concave shape.

Next, as shown in FIG. 10B, on the information patterns 1002 of the L0 layer, an L0 layer recording film 1003 was formed. The L0 layer recording film 1003 typically includes a reflective layer which does not transmit light or a reflective layer. According to this example, an L0 reflective film was formed by, for example, a sputtering method, an organic coloring matter-based L0 recording film was formed employing a spin coating method, and then a dielectric film was formed employing the sputtering method.

As shown in FIG. 10C, an intermediate layer forming-2p resin (photoreactive curable resin) 1004 for forming an intermediate layer between the L0 layer and the L1 layer was applied thereto with a thickness of, for example, 25 μm, which is similar to that of Example 1.

As shown in FIG. 10D, the transparent stamper 1000 is a transparent stamper according to this example, and has information patterns 1005 (pits or guide grooves) of the L1 layer formed therein. Each information track is convex with respect to the stamper.

The polycarbonate substrate 1001 applied with the intermediate layer forming-2p resin 1004 was superimposed on the transparent stamper 1000 in a direction in which the information patterns of the L0 layer were opposed to the information patterns of the L1 layer. At this time, alignment thereof was performed using a center hole (not shown). After that, the ultraviolet ray was irradiated thereon through the transparent stamper 1000 to cure the intermediate layer forming-2p resin 1004. In order to cure the intermediate layer-forming 2p resin 1004, there was required UV irradiation time of less than 2 seconds.

As shown in FIG. 10E, after the intermediate layer forming-2p resin 1004 is cured, the transparent stamper 1000 is peeled, thereby forming the information patterns 1005 of the L1 layer. The transparent stamper 1000 thus peeled does not deteriorate even by being irradiated with the UV light beam, and can be repeatedly used.

As shown in FIG. 10F, on the information patterns 1005 of the L1 layer, an L1 layer recording film 1006 was formed. The L1 layer recording film 1006 is formed of a semitransparent film. An L1 high refractive index film and an L1 reflective film were formed by, for example, the sputtering method, an organic coloring matter-based L1 recording film was formed employing the spin coating method, and then a dielectric film was formed employing the sputtering method.

As shown in FIG. 10G, on the L1 layer recording film 1006, a cover layer-forming 2p resin (resin protective layer) 1007 was formed. In the same manner as in Example 1, the cover layer-forming 2p resin 1007 was applied thereto with a thickness of, for example, 75 μm. After that, the ultraviolet ray from the UV light source was irradiated thereon to cure the cover layer-forming 2p resin 1007, thereby completing the two-layered optical recording medium according to this example.

An evaluation of signal reproduction was performed with respect to the optical disk thus produced using an optical system having a laser wavelength of 405 nm and an objective lens NA of 0.85, at a linear speed of 4.92 m/s, and using random data of (1-7) modulation having a capacity of 25 GB. When equalization was performed using a limit equalizer to measure a data-to-clock jitter, values of 5.5% in the L0 layer and 6.7% in the L1 layer were obtained.

### Example 9

In Example 9, a description is made of a method of producing an optical disk for recording/reproduction through a polycarbonate (PC) substrate as an example. Here, an information recording layer at a side closer to an optical system for recording/reproduction of the optical disk is called L1, and an information recording layer at a side far from an optical system for recording/reproduction of the optical disk is called L0.

An L0-forming transparent stamper 1100 was produced in the same method as in Example 8 except that the track pitch T was changed to 400 nm. Each information track side thereof is convex with respect to the stamper.

Next, in Example 9, the transparent stamper 1100 according to the present invention and an L1-forming substrate which includes information tracks each having a concave shape were used to produce an optical disk using an organic recording material.

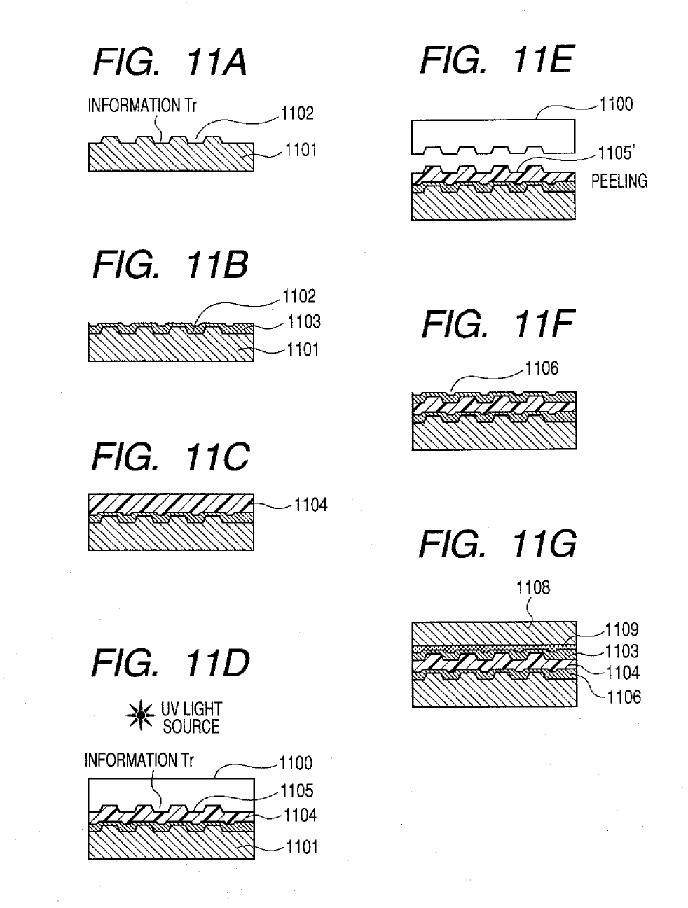

A description is made of the optical disk with reference to FIGS. 11A to 11G. FIGS. 11A to 11G each show a sectional view of a half part of a rotationally-symmetrical disk having a center hole, and the center hole of each of the substrate and the stamper is omitted. All the processes are illustrated with an incident surface of a light beam for recording/reproduction facing downward.

First, as shown in FIG. 11A, by injection molding, a polycarbonate (PC) substrate 1101 having a thickness of 0.6 mm, a diameter of 120 mm, and a center hole diameter of 15 mm, in which information patterns 1102 (pits or guide grooves) of the L1 layer were formed, was formed. Each information track has a concave shape.

Next, as shown in FIG. 11B, on the information patterns 1102 of the L1 layer, an L1 layer recording film 1103 was formed. The L1 layer recording film is formed of a semitransparent film. An organic coloring matter-based L1 recording film was formed by, for example, a spin coating method, and then an L1 reflective film was formed by the sputtering method.

As shown in FIG. 11C, an intermediate layer forming-2p resin (photoreactive curable resin) 1104 for forming an intermediate layer between the L0 layer and the L1 layer was applied thereto with a thickness of, for example, 35 μm.

As shown in FIG. 11D, the transparent stamper 1100 is a transparent stamper according to this example, and has information patterns 1105 (pits or guide grooves) of the L0 layer formed therein. Each information track is convex with respect to the stamper. The polycarbonate substrate 1101 applied with the intermediate layer forming-2p resin 1104 was superimposed on the transparent stamper 1100 in which information patterns of the L0 layer were formed, in a direction in which the information patterns of the L0 layer were opposed to the information patterns of the L1 layer. At this time, alignment thereof was performed using a center hole (not shown). After that, the ultraviolet ray was irradiated thereon through the transparent stamper 1100 to cure the intermediate layer forming-2p resin 1104. In order to cure the intermediate layer-forming 2p resin 1104, there was required UV irradiation time of less than 2 seconds.

As shown in FIG. 1E, after the intermediate layer forming-2p resin 1104 is cured, the transparent stamper 1100 is peeled, thereby forming the information patterns 1105 of the L0 layer. The transparent stamper 1100 thus peeled does not deteriorate even by being irradiated with the UV light beam, and can be repeatedly used.

As shown in FIG. 11F, on the information patterns 1105 of the L0 layer, an L0 layer recording film 1106 was formed. The L0 layer recording film typically includes a reflective film which does not transmit light or a reflective film. According to this example, an organic coloring matter-based L0 recording film was formed by, for example, the spin coating method, and then an L0 reflective film was formed employing the sputtering method.

As shown in FIG. 11G, to the L0 layer recording film, a polycarbonate substrate 1108 having a thickness of 0.6 mm was bonded by employing a UV curing adhesive material 1109, thereby completing the two-layered optical recording medium according to this example.

An evaluation of signal reproduction was performed with respect to the optical disk thus produced using an optical system having a laser wavelength of 405 nm and an objective lens NA of 0.65, and employing ETM (8/12) modulation having a capacity of 15 GB. When a simulated bit error rate (SbER) was measured, values of 4.2×10⁻⁶ in the L0 layer and 7.0×10⁻⁶ in the L1 layer were obtained.

The present invention is characterized in that a resist layer containing a tungsten oxide is formed on a transparent substrate which can be repeatedly used, and a stamper having uneven pattern which correspond to information signal patterns (pits or guide grooves) formed in the resist layer is used. Therefore, the structure of the stamper, the stacking order or stacking direction of the information recording layers, the material of the recording layer, and the like are not limited to those of the above-mentioned examples.

### Example 10

In Example 10, a description is made of a molybdenum oxide MoO having a composition in which oxygen is lost from a stoichiometric composition as a resist as an example. The molybdenum oxide MoO used in Example 10 has a film whose state is changed by irradiation of light for exposure, and corresponds to a positive type resist in which the exposed part becomes concave by the development using an alkali solution.

As a glass substrate, a quartz substrate having a thickness of 1 mm, an outer diameter of 120 mm, and an inner diameter of 15 mm was used. First, on the quartz substrate, molybdenum oxide MoO having the composition in which oxygen was lost from the stoichiometric composition was formed. Sputtering was performed on a Mo metal target in an atmosphere of Ar gas of 50 sccm and O₂ gas of 11.5 sccm, to thereby form the MoO. Used was a composition having the film thickness before exposure of 100 nm and the absorptivity of 50% with respect to the exposure light having a wavelength of 351 nm.

Next, the light for exposure was converged on the resist, and was moved toward a radius direction of the quartz substrate while the quartz substrate was rotated, thereby performing pattern exposure whose patterns correspond to information patterns (pits or guide grooves) of the L1 layer on the resist. According to Example 10, as a condition for exposing a data recording area, a linear speed was set to 1.0 m/s, and power was set to 0.8 mW, and a track pitch TP was set to 320 nm.

Next, the resist of the exposed part was subjected to etching using the alkali developer, and development was performed so that the depth of each groove of the data recording area be d=20 nm, to thereby produce a transparent stamper. Here, each information track side thereof is concave with respect to the stamper.

The transparent stamper has a transmittance of 40% at the maximum with respect to light having a wavelength of 350 nm to 400 nm in a state after the development.

Next, an optical disk was produced by the method of producing an optical disk similar to that of Example 6. When the optical disk was evaluated in the same manner as in Example 6, the characteristic equivalent to that of Example 6 was obtained. The UV irradiation time necessary for curing the intermediate layer-forming 2p resin was less than 2 seconds.

This application claims the benefit of Japanese Patent Application No. 2006-020895, filed Jan. 30, 2006, and Japanese Patent Application No. 2006-292528 Oct. 27, 2006 which are hereby incorporated by reference herein in their entirety.

1.-10. (canceled)

11. A method of producing a multilayer optical recording medium, comprising:
(a) a step of forming a recording layer on a support substrate formed one of a pit or a guide groove;
(b) a step of forming an intermediate layer formed of a photoreactive curable resin onto the recording layer;
(c) a step of irradiating the intermediate layer with an ultraviolet ray through a stamper having one of a pit or a guide groove formed on a translucent flat substrate by using an inorganic resist layer to transfer the one of the pit or the guide groove onto the intermediate layer, wherein the inorganic resist layer contains an oxide of an inorganic material having a composition wherein oxygen content is less than a stoichiometric oxygen content; and
(d) a step of stacking a recording layer on the intermediate layer.

12. A method of producing a multilayer optical recording medium according to claim 11, wherein the stamper has an absorptivity of 10% or more with respect to exposure light which is used in patterning the inorganic resist layer, and has a transmittance of 15% or more with respect to an ultraviolet ray used in curing a photo-curable resin.

13. A method of producing a multilayer optical recording medium according to claim 11, further comprising (e) a step of reusing the stamper for producing another multilayer optical recording medium.

14. A method of producing a multilayer optical recording medium according to claim 13, wherein the inorganic resist layer contains at least one of tungsten and molybdenum.

15. (canceled)

16. A method of producing a multilayer optical recording medium according to claim 11, wherein the substrate comprises any one of glass, quartz, and transparent ceramic.

17. A method of producing a multilayer optical recording medium, comprising:
(a) a step of forming a first intermediate layer formed of a photoreactive curable resin on a support substrate;
(b) a step of irradiating the first intermediate layer with an ultraviolet ray through a stamper having one of a pit or a guide groove formed on a translucent flat substrate by using an inorganic resist layer to transfer the one of the pit or the guide groove onto the intermediate layer;
(c) a step of stacking a recording layer on the first intermediate layer, wherein the inorganic resist layer contains an oxide of an inorganic material having a composition wherein oxygen content is less than a stoichiometric composition; and
(d) a step of forming a second intermediate layer formed of the photoreactive curable resin onto the recording layer.
